(19) United States
(12) Patent Application Publication
(10) Pub. No.: US 2018/0335821 A1
(43) Pub. Date: Nov. 22, 2018

(54) INFORMATION PROCESSING APPARATUS, CONTROL METHOD, COMPUTER, AND COMPUTER PROGRAM

(71) Applicant: KONICA MINOLTA, INC., Tokyo (JP)

(72) Inventors: Masahiro Kamiya, Toyohashi-shi (JP); Takeshi Tamada, Toyohashi-shi (JP); Yoshihito Sasamoto, Tokyo (JP); Katsuyuki Ikuta, Hamamatsu-shi (JP); Shota Igo, Toyokawa-shi (JP)

(73) Assignee: KONICA MINOLTA, INC., Tokyo (JP)

(21) Appl. No.: 15/972,522

(22) Filed: May 7, 2018

(30) Foreign Application Priority Data
May 18, 2017 (JP) 2017-099296

(51) Int. Cl. G06F 1/30; G06F 1/26

(52) U.S. Cl. CPC G06F 1/30; H05K 7/20936; G06F 1/263

(57) ABSTRACT

An information processing apparatus includes a first device and a second device, the first device includes a first power receiving member, a first switcher, a first power supply circuit, a failure detector, a second switcher, and a first electrical load, and the second device includes a second power receiving member, a second power supply circuit, a distributor, a third switcher, a second electrical load, and a hardware processor.

The entire disclosure of Japanese patent Application No. 2017-099296 filed on May 18, 2017, is incorporated herein by reference in its entirety.

### BACKGROUND

### Technological Field

The present invention relates to a technology for enabling stable power supply to an electrical load.

### Description of the Related art

Necessity to secure power is caused because an electric device has a large number of functions, or an electric device has a tendency to have a plurality of power supply units to reliably operate the electric device when an electric power unit breaks down.

For example, in a server device as a computer system that provides various services, reliability to continue to operate without failure is required for a long time. For this reason, the server device includes a spare power supply unit so as to continue to operate even if one power supply unit breaks down.

Further, for example, in an information processing apparatus in which an image forming device and a server device are integrally configured, a total of three power supply units including two power supply units for the server device and one power supply unit for the image forming device are provided to secure the reliability of the server device.

Patent Document 1: JP 2007-316245 A

Patent Document 2: JP 2007-049893 A

Patent Document 3: JP 2008-070560 A

Patent Document 4: JP 2012-047935 A

As described above, for example, the information processing apparatus in which the image forming device and the server device are integrally configured has a configuration including a total of two power supply units including one power supply unit for the server device and one power supply unit for the image forming device, and if the respective devices can use the other power supply units as spare power supply units, the cost of the information processing apparatus as a whole can be reduced.

However, in this example, in a case where the power supply unit on the server device side breaks down, power is supplied from the power supply unit on the image forming device side to the server device. Since suppliable power from one power supply unit has an upper limit (rated value), when the total of power required in the image forming device and the server device exceeds the rated value, the image forming device or the server device needs to limit the power and may not be able to continue the operation of the device.

### SUMMARY

An object of the present invention is to provide an information processing apparatus enabling continuous operation of both devices even when a power supply unit of one of the devices does not normally output power while solving the above problem.

To achieve the abovementioned object, according to an aspect of the present invention, an information processing apparatus reflecting one aspect of the present invention comprises a first device and a second device, the first device comprising a first power receiving member, a first switcher, a first power supply circuit, a failure detector, a second switcher, and a first electrical load, the second device comprising a second power receiving member, a second power supply circuit, a distributor, a third switcher, a second electrical load, and a hardware processor, wherein the first switcher switches connection between the first power receiving member connected to an external power supply and the first power supply circuit to connection between the first power receiving member and the third switcher by a request of the second device, the first power supply circuit converts power supplied via the first power receiving member to generate first output power in a case where the first power supply circuit is connected to the first power receiving member by the first switcher, the failure detector detects a failure in the first power supply circuit, and notifies the second device of detection of the failure when the failure detector has detected the failure, the second switcher switches connection between the first power supply circuit and the first electrical load to connection between the distributor and the first electrical load when the failure has been detected, the first electrical load receives supply of the first output power from the first power supply circuit, and receives supply of power from the distributor when the failure has been detected, the second power supply circuit and the third switcher are connected to the external power supply via the second power receiving member and a power receiving path having a rated value that defines a maximum suppliable power, the second power supply circuit converts supplied power to generate second output power, the distributor supplies part of the second output power to the second switcher when the failure has been notified, the third switcher switches connection between the second power receiving member and the second electrical load to connection between the second power receiving member and a part of the second electrical load and connection between the first switcher and a remaining part of the second electrical load when the failure has been notified, the second electrical load receives supply of power via the second power receiving member, and the part of the second electrical load receives supply of power via the second power receiving member and the remaining part of the second electrical load receives supply of power via the first power receiving member when the failure has been detected, and the hardware processor requests the first device to supply power when the power supplied via the second power receiving member exceeds the rated value due to the supply of power to the second switcher by the distributor.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are not intended as a definition of the limits of the present invention:

FIG. 1 is a diagram illustrating a schematic configuration of an image forming system;

FIG. 2 is a diagram illustrating a detailed configuration regarding a power system and the like in the image forming system;

FIG. 3 illustrates an example of a power table;

FIG. 4 illustrates an example of a message displayed on an operation panel;

FIG. 5 is a sequence diagram illustrating an example of an operation of the image forming system;

FIG. 6 is a sequence diagram illustrating another example of the operation of the image forming system 10;

FIG. 7 is a sequence diagram illustrating still another example of the operation of the image forming system; and

FIG. 8 is a diagram illustrating a detailed configuration regarding a power system and the like in a refrigerator system.

### DETAILED DESCRIPTION OF EMBODIMENTS

Hereinafter, one or more embodiments of the present invention will be described with reference to the drawings. However, the scope of the invention is not limited to the disclosed embodiments.

### 1. Embodiment

An image forming system (information processing apparatus) 10 as an embodiment according to the present invention will be described with reference to the drawings.

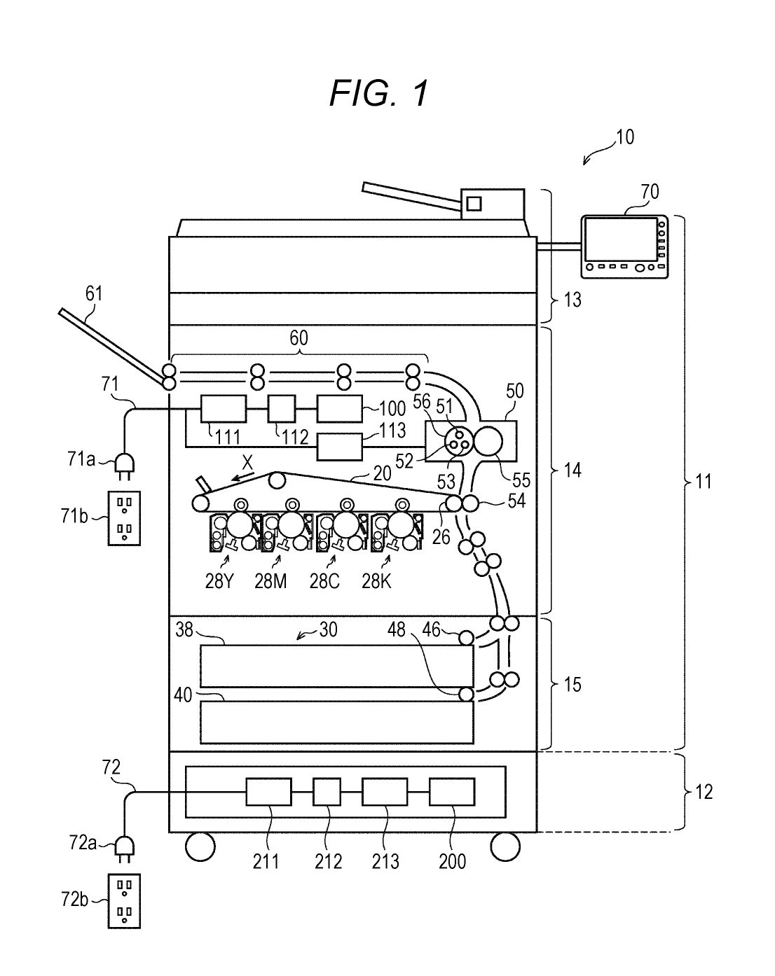

FIG. 1 is a diagram illustrating a schematic configuration of the image forming system (information processing apparatus) 10.

As illustrated in FIG. 1, the image forming system 10 includes a multi-function peripheral (MFP) section (second device) 11 that forms an image on a recording sheet by an electrophotographic method and a server section (first device) 12. Each of the MFP section 11 and the server section 12 has an electrical load.

1.1 MFP Section 11

The MFP section 11 is a tandem color multifunction peripheral having functions of a scanner, a printer, and a copier.

The MFP section 11 includes an image reader 13 that reads a document image, a printer 14 that prints and reproduces the read image on a recording sheet, and a sheet feeder 15 that holds and feeds the recording sheet.

The image reader 13 includes an automatic document conveyance device. The automatic document conveyance device conveys documents set on a document tray to a document glass plate one by one.

The image reader 13 reads an image of the document conveyed to a predetermined position on the document glass plate by the automatic document conveyance device by movement of a scanner. Reflection light of the document image obtained by irradiation with an exposure lamp installed in the scanner is received by a CCD color image sensor (hereinafter simply referred to as “CCD sensor”), is converted into an electrical signal by the CCD sensor, and is further A/D converted to obtain image data including multi-value digital signals of red (R), green (G), and blue (B).

The image data of each color component obtained in the image reader 13 undergoes various types of data processing in an MFP control board 100 and is further converted into image data of each reproduced color of yellow (Y), magenta (M), cyan (C), or black (K). Hereinafter, the reproduced colors of yellow, magenta, cyan, and black are represented as Y, M, C, and K, and Y, M, C, and K are added as subscripts to numbers of constituent components related to the reproduced colors.

The image data of the Y to K colors are stored in image memories included in the MFP control board 100 for each reproduced color, and are read for each scanning line at timing described below in synchronization with supply of the recording sheet and become drive signals of corresponding LED arrays.

The printer 14 forms an image by an electrophotographic method. The printer 14 includes an intermediate transfer belt 20, a drive roller, a driven roller, and a backup roller that stretch the intermediate transfer belt 20, image forming units 28Y, 28M, 28C, and 28K facing the intermediate transfer belt 20 and arranged along a traveling direction X of the intermediate transfer belt 20 at predetermined intervals, and a fixer 50.

Each of the image forming units 28Y, 28M, 28C, and 28K includes a photosensitive drum as an image carrier, an LED array for exposing and scanning a surface of the photosensitive drum, a charger, a developer, a cleaner, a primary transfer roller, and the like.

The sheet feeder 15 includes sheet feed cassettes 38 and 40 for storing recording sheets having different sizes, pickup rollers 46 and 48 for sending out the recording sheets from the respective paper feed cassettes to a conveyance path, a resist roller for timing sending the recording sheet to a secondary transfer roller 54.

Each photosensitive drum is uniformly charged by the charger after a residual toner on the surface is removed by the cleaner before receiving exposure by the corresponding LED, and when the photosensitive drum receives the exposure in the uniformly charged state, an electrostatic latent image is formed on the surface of the photosensitive drum.

Each electrostatic latent image is developed by the developer of each color, thereby a toner image of each color is formed on the surface of the photosensitive drum, and the toner image formed on the surface of the photosensitive drum is sequentially transferred onto a surface of the intermediate transfer belt 20 by an electrostatic action of a primary transfer roller disposed on the back side of the intermediate transfer belt 20.

At this time, image forming operations of the colors are executed delaying timing from an upstream side to a downstream side in the traveling direction so that the toner images of Y to K colors are superimposed and transferred on the same position of the traveling intermediate transfer belt 20.

Meanwhile, the recording sheet is fed from one of the sheet feed cassettes of the sheet feeder 15 in time with the image forming operations of the image forming units 28Y to 28K and is conveyed on the conveyance path to a position (secondary transfer position) where the secondary transfer roller 54 and the backup roller 26 face each other across the intermediate transfer belt 20. At the secondary transfer position, the toner images of the Y to K colors on the intermediate transfer belt 20 are secondarily transferred to the recording sheet by the electrostatic action of the secondary transfer roller 54.

The recording sheet on which the toner images of the Y to K colors have been secondarily transferred is further conveyed to the fixer 50. A heating roller 56 of the fixer 50 is heated to a fixing temperature by a fixing heater (a heating member or a second electrical load) 51, 52 or 53. When the recording sheet passes through the fixer 50, toner particles on the surface of the recording sheet are fused and fixed on the surface by heating and pressurization by the heating roller 56 and a pressure roller (pressure member) 55, and the recording sheet is sent out to a conveyance unit 60 after passing through the fixer 50.

In the conveyance unit 60, the conveyance path is formed in a horizontal direction. The conveyance unit 60 outputs the recording sheet to a discharge tray 61 by a plurality of conveyance roller pairs. An operation panel 70 is provided above the MFP section 11.

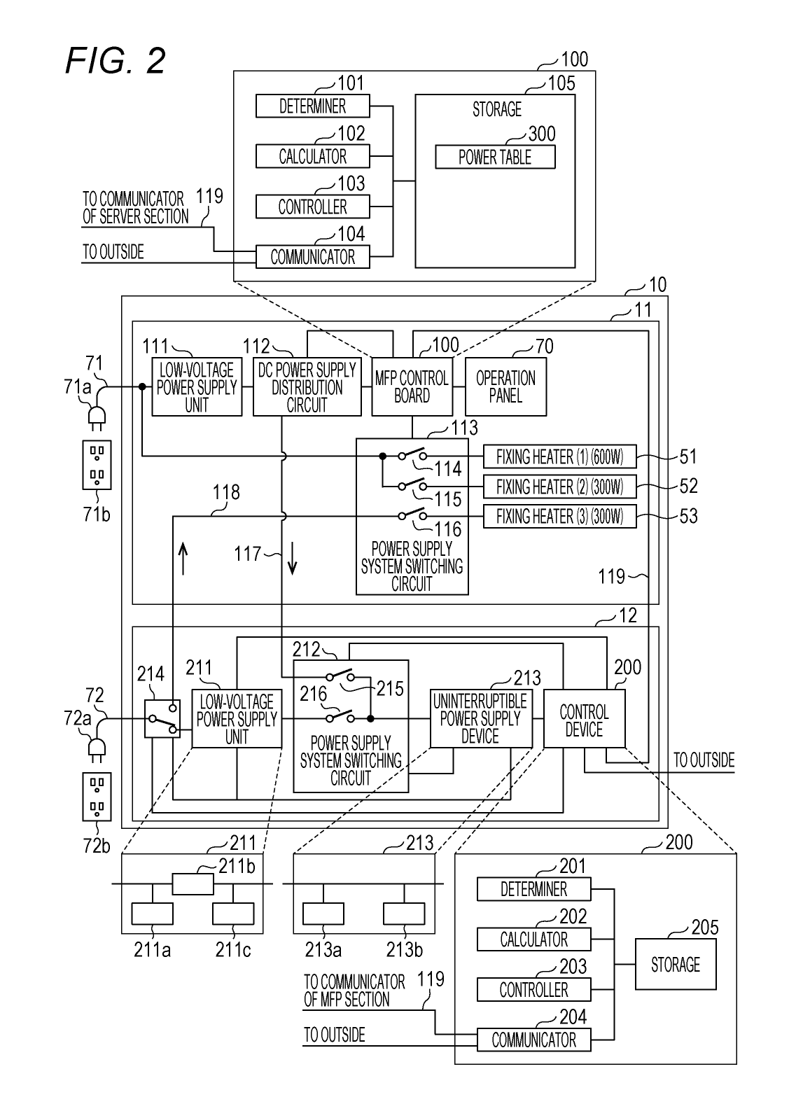

As illustrated in FIG. 2, the MFP section 11 further includes a low-voltage power supply unit (second power supply circuit) 111, a DC power supply distribution circuit (distributor) 112, and a power supply system switching circuit (third switcher) 113. Power is supplied to the MFP section 11 from an external alternating-current power supply (commercial power supply) via an external outlet 71b, a plug (second power receiving member) 71a, and a power cord (second power receiving member) 71 through a power receiving path. The power receiving path connected to the external alternating-current power supply has a rated value (for example, 1500 W) that defines a maximum suppliable power. The power supplied via the power cord 71 is supplied to the fixing heaters 51 and 52 via the power supply system switching circuit 113. Further, an alternating current supplied via the power cord 71 is converted into a direct current by the low-voltage power supply unit 111 and is supplied to the constituent elements of the server section 12 and the MFP section 11 via the DC power supply distribution circuit 112.

Note that, in the MFP section 11, an electrical part that consumes power, such as the fixing heaters 51, 52 or 53, the low-voltage power supply unit 111, the DC power supply distribution circuit 112, the power supply system switching circuit 113, the MFP control board 100, the operation panel 70, a motor, another electrical circuit, an exposure element sensor, or the like is an electrical load.

Hereinafter, the low-voltage power supply unit 111, the DC power supply distribution circuit 112, the power supply system switching circuit 113, the MFP control board 100, the fixing heaters 51 to 53, and the operation panel 70 will be described.

(1) Low-Voltage Power Supply Unit 111

The low-voltage power supply unit 111 is connected to the outlet 71b via the plug 71a and the power cord 71, and receives supply of alternating-current power from the outlet 71b.

The low-voltage power supply unit 111 converts the alternating current supplied from the outlet 71b into a direct current. The direct current has, for example, a voltage of 5 V (volts). The low-voltage power supply unit 111 supplies the direct current to the DC power supply distribution circuit 112.

Here, the current flowing in the power cord 71 connecting the outlet 71b and the low-voltage power supply unit 111 needs to be suppressed to equal to or less than 15 A that is the rated current of the power cord 71 (or equal to or less than 1500 W in power in the case where the rated value of the power supply voltage is 100 V (volts)).

(2) DC Power Supply Distribution Circuit 112

The DC power supply distribution circuit 112 receives supply of the direct current from the low-voltage power supply unit 111, and supplies the supplied direct current to the MFP control board 100 and the units (excluding the fixing heaters 51, 52, and 53) of the MFP section 11. Further, the DC power supply distribution circuit 112 supplies the direct current supplied from the low-voltage power supply unit 111 to the server section 12 via the power cord 117 by the control of the MFP control board 100.

(3) Power Supply System Switching Circuit 113

The power supply system switching circuit 113 includes switches 114, 115, and 116.

The power system switching circuit 113 is connected to the outlet 71b via the plug 71a and the power cord 71, and the alternating-current power is supplied to the power supply system switching circuit 113 from the outlet 71b.

Connection/non-connection between the fixing heater 51 and the power cord 71 is switched by switching the switch 114 by the control of the MFP control board 100. Further, connection/non-connection between the fixing heater 52 and the power cord 71 is switched by switching the switch 115 by the control of the MFP control board 100. Further, connection/non-connection between the fixing heater 53 and a power cord 118 is switched by switching the switch 116 by the control of the MFP control board 100. Here, the power cord 118 is connected to a switch (first switcher) 214 described below of the server section 12.

The power supply system switching circuit 113 outputs the alternating current supplied from the outlet 71b via the plug 71a and the power cord 71 of the MFP section 11 to either the fixing heater 51 or 52 by turning on the switch 114 or 115 by the control of the MFP control board 100.

Further, the power supply system switching circuit 113 outputs an alternating current supplied from an outlet (first external power supply) 72b via a plug (first power receiving member) 72a, a power cord (first power receiving member) 72, the switch 214, and the power cord 118 of the server section 12 to the fixing heater 53 by turning on the switch 116 by the control of the MFP control board 100.

Note that the power supply system switching circuit 113 may perform full-wave rectification of the alternating current supplied from the outlet 71b and may output the full-wave rectified current to either the fixing heater 51 or 52. In addition, the power supply system switching circuit 113 may perform full-wave rectification of the alternating current supplied from the outlet 72b and may output the full-wave rectified current to the fixing heater 53. Further, the power supply system switching circuit 113 may control heating values of the fixing heaters 51, 52, and 53 so that a surface temperature of the heating roller 56 becomes a target temperature.

(4) MFP Control Board 100

The MFP control board 100 includes a determiner 101, a calculator 102, a controller 103, a communicator 104, and a storage 105.

Specifically, the MFP control board 100 includes a CPU, a ROM, a RAM, a network connection card, and the like. A control computer program is stored in the ROM, and the determiner 101, the calculator 102, and the controller 103 perform respective functions as the CPU is operated according to the control computer program. Further, the communicator 104 performs its function as the network connection card is operated. The storage 105 includes a ROM and a RAM.

The communicator 104 is connected to the server section 12 via a LAN cable 119 and is connected to a LAN as an external network via another LAN cable.

Note that the MFP control board 100 is an example of an electrical load.

(a) Outline of Power Control in the MFP Control Board 100

Here, an outline of a method of controlling power supply in the image forming system 10 (a) in a case where the low-voltage power supply unit (first power supply circuit) 211 described below included in the server section 12 has broken down and (b) in a case where the plug 72a of the server section 12 is unplugged from the outlet 72b and the power cord 72 is not connected to the outlet 72b will be described.

In the case of (a), a method of controlling the current flowing in the power cord 71 of the MFP section 11 not to exceed the rated value and a method of controlling the current flowing in the power cord 71 of the MFP section 11 to temporarily exceed the rated value can be adopted.

(i) A case of adopting the method of controlling the current flowing in the power cord 71 of the MFP section 11 not to exceed the rated value is as follows.

When a failure of the low-voltage power supply unit 211 has been detected, power necessary in the MFP section 11 and power necessary in the server section 12 are calculated in advance, and when total power exceeds the rated value, some of the fixing heaters of the MFP section 11 is turned off, and then the direct current is supplied from the MFP section 11 to the server section 12. Further, the MFP section 11 receives supply of the alternating current from the power cord 72 of the server section 12, and switches part of the power supply to the fixing heater (turned off) to the alternating current from the power cord 72 of the server section 12. In this manner, both the current flowing in the power cord 71 of the MFP section 11 and the current flowing in the power cord 72 of the server section 12 can be set within the rated value.

(ii) A case of adopting the method of controlling the current flowing in the power cord 71 of the MFP section 11 to temporarily exceed the rated value is as follows.

In “Ordinance Concerning Technical Requirements for Electrical Appliances and Materials”, the conformity criteria for earth leakage circuit breakers are defined as follows (extracts).

a When the current equal to 200% of the rated current is turned on, it shall operate automatically within the following operation time.

Rated current (A): 30 or less

Operation time (minute): 2

b It shall operate automatically within the following operation time when passing current equal to 125% of the rated current.

Rated current (A): 30 or less

Operation time (minute): 60

According to the conformity criteria, the earth leakage circuit breaker operates within 60 minutes when a current of 125% of the rated current flows. Also, when a current of 200% of the rated current flows, the earth leakage circuit breaker operates within 2 minutes. Therefore, according to the conformity criteria, the problem that the earth leakage circuit breaker operates does not occur as long as the current falls within the conformity criteria even when a failure or the like occurs in the low-voltage power supply unit 211 of the server section 12, the current is supplied from the MFP section 11 to the server section 12, and the current flowing in the power cord 71 of the MFP section 11 temporarily exceeds the rated value (15 A).

Therefore, when the failure of the low-voltage power supply unit 211 has been detected, first, the direct current is supplied from the MFP section 11 to the server section 12. Next, the MFP section 11 calculates the power necessary in the MFP section 11 and the power necessary in the server section 12, and when the total power exceeds the rated value, the MFP section 11 receives supply of the alternating current from the power cord 72 of the server section 12. Next, the MFP section 11 switches part of the power supply to the fixing heater to the alternating current from the power cord 72 of the server section 12. In this manner, both the current flowing in the power cord 71 of the MFP section 11 and the current flowing in the power cord 72 of the server section 12 can be set within the rated value.

(iii) In the case of (b), when disconnection of the power cord 72 has been detected, first, the direct current is supplied from the MFP section 11 to the server section 12. Next, the MFP section 11 calculates the power necessary in the MFP section 11 and the power necessary in the server section 12, and when the total power exceeds the rated value, the MFP section 11 halves a process speed and a conveyance speed of the recording sheet, and halves the power supply to the fixing heater. In this manner, the current flowing in the power cord 71 of the MFP section 11 can be set within the rated value.

(b) Storage 105

The storage 105 stores a power table 300.

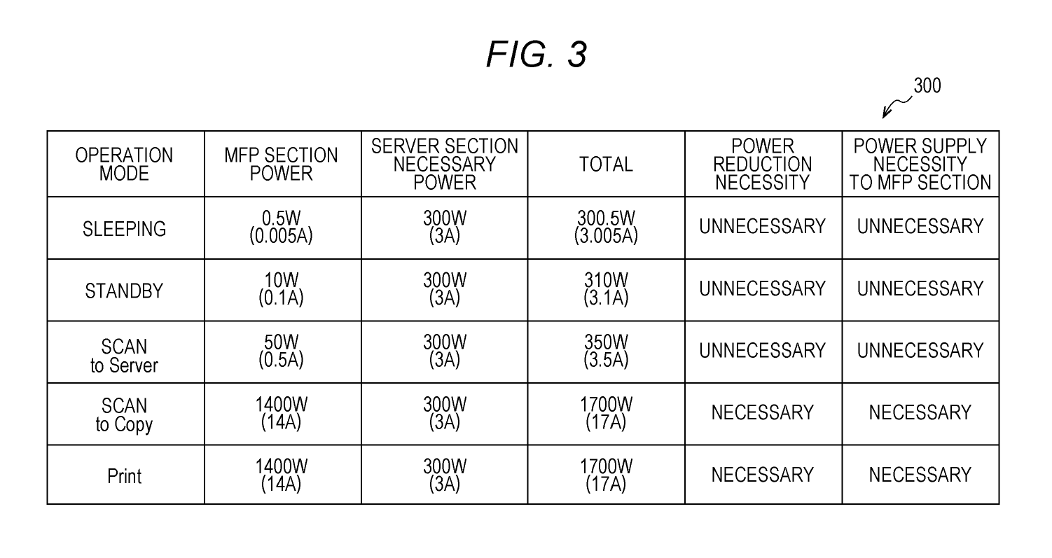

For example, as illustrated in FIG. 3, the power table 300 includes a plurality of pieces of power information, and each power information includes an operation mode, MFP section power, server section necessary power, total, power reduction necessity, and power supply necessity to MFP section.

Here, the operation mode indicates the operation mode set in the MFP section 11. The operation modes include “sleeping”, “standby”, “scan to Server”, “scan to Copy”, “print”, and the like.

The “scan to Server” is a mode for outputting image data read by the image reader 13 to the server section 12. The “scan to Copy” is a mode for forming an image on the recording sheet by the printer 14 on the basis of the image data read by the image reader 13, and outputting the recording sheet. The “print” is a mode for forming an image on the recording sheet by the printer 14 on the basis of a print job received from an external personal computer (PC) or the like, and outputting the recording sheet. The “standby” is a mode for waiting for transition to the modes of the “scan to Server”, “scan to Copy”, and the “print”. The “sleeping” is a power saving mode for saving power consumed in the MFP section 11 after “standby” continues for a predetermined time, for example, 5 minutes.

The MFP section power indicates the power consumption (and the current in parentheses) required in the

MFP section 11 in a corresponding operation mode. In the case where the operation modes are “sleeping”, “standby” and “scan to Server”, the MFP section power indicates low values (0.5 W (watts) (0.005 A (amperes)), 10 W (0.1 A), and 50 W (0.5 A)). On the other hand, when the operation mode is “scan to Copy” or “print”, the MFP section power indicates a high value (1400 W (14 A)).

The server section necessary power indicates the power consumption (and the current in parentheses) required in the server section 12 in a corresponding operation mode. In any of the operation modes, the server section necessary power is 300 W (3 A).

Although the server section necessary power is assumed to be a fixed value, the server section necessary power is not limited to the fixed value. The server section necessary power may vary depending on an optional circuit or device mounted in the server section 12 or a processing mode in the server section 12. In such a case, the server section 12 keeps varying power, and notifies the controller 103 of the MFP section 11 of the varying power.

The total indicates a total value of the power consumption required in the MFP section 11 and the power consumption required in the server section 12 (a total value of the current required in the MFP section 11 and the current required by the server section 12) in a corresponding operation mode.

The power reduction necessity indicates whether reduction of the power consumption is necessary in the MFP section 11 in a corresponding operation mode. “Unnecessary” indicates that reduction of the power consumption is not necessary in the MFP section 11, and “necessary” indicates that reduction of the power consumption is necessary in the MFP section 11. In the case where the operation modes are “sleeping”, “standby”, and “scan to Server”, the power reduction necessity is “unnecessary”. On the other hand, in the case where the operation mode is “scan to Copy” and “print”, the power reduction necessity is “necessary”.

The power reduction necessity is mainly determined according to whether fixation of toner particles onto the surface of the recording sheet by heating and pressurization by the fixer 50 is necessary in each operation mode. This is because the power consumption by the fixing heater included in the fixer 50 is larger than the power consumption by other constituent elements.

The power supply necessity to MFP section indicates whether the power supply is necessary from the server section 12 to the MFP section 11 in each operation mode. “Unnecessary” indicates that the power supply is not necessary from the server section 12 to the MFP section 11, and “necessary” indicates that the power supply is necessary from the server section 12 to the MFP section 11. In the case where the operation modes are “sleeping”, “standby” and “scan to Server”, the power supply necessity to MFP section is “unnecessary”. On the other hand, in the case where the operation modes are “scan to Copy” and “print”, the power supply necessity to MFP section is “necessary”.

The power supply necessity to MFP section is determined according to whether fixation of toner particles onto the surface of the recording sheet by heating and pressurization by the fixer 50 is necessary in each operation mode, similarly to the power reduction necessity.

(c) Determiner 101

The determiner 101 determines whether the total current of the MFP section 11 and the server section 12 is 15 A or more.

(d) Calculator 102

The calculator 102 calculates the total power consumption (total current) of the MFP section 11 and the server section 12, using the power table 300 stored in the storage 105, when receiving a failure signal indicating that a failure has occurred in the low-voltage power supply unit 211 of the server section 12 or a plug unplugged signal indicating that the plug 72a is unplugged.

For example, in the case where the operation mode is “sleeping”, the calculator 102 calculates 300.5 W (3.005 A) as the total power consumption (total current) of the MFP section 11 and the server section 12, using the power table 300.

Further, for example, in the case where the operation mode is “print”, the calculator 102 calculates 1700 W (17 A) as the total power consumption (total current) of the MFP section 11 and the server section 12, using the power table 300.

(e) Controller 103

(Reception of Failure Signal and Plug Unplugged Signal)

The controller 103 receives the failure signal indicating that a failure has occurred in the low-voltage power supply unit 211 of the server section 12 and the plug unplugged signal indicating that the plug 72a of the server section 12 is unplugged from the server section 12 via the LAN cable 119 and the communicator 104.

The controller 103 controls the DC power supply distribution circuit 112 to supply the direct current to the server section 12 (a) when receiving the failure signal in the method of controlling the current flowing in the power cord 71 to temporarily exceed 15 A, (b) when receiving the failure signal and the power consumption of the MFP section 11 is limited in the method of controlling the current flowing in the power cord 71 not to exceed 15 A, or (c) when receiving the plug unplugged signal.

(Power Supply Request)

When the controller 103 has received the failure signal and the determiner 101 determines that the total current is 15 A or more, the controller 103 requests the server section 12 to supply the power to the MFP section 11 via the communicator 104 and the LAN cable 119.

(Power Supply Start)

The controller 103 receives a start signal indicating that the supply of power has started from the power cord 72 to the MFP section 11, from the server section 12 via the LAN cable 119 and the communicator 104.

(Power Limitation)

The controller 103 limits the power consumption in the MFP section 11 as follows.

(a) In the case of the method of controlling the current flowing in the power cord 71 to temporarily exceed 15 A

In the case of the method of controlling the current flowing in the power cord 71 to temporarily exceed 15 A, the controller 103 performs power limitation of the MFP section 11 as follows when receiving a start signal that indicates start of supply of power from the server section 12.

The controller 103 turns OFF the switch 114 to turn off the fixing heater 51, and turns ON the switch 115 to turn on the fixing heater 52. Further, the controller 103 turns ON the switch 116 to turn on the fixing heater 53. The fixing heater 52 is turned on by the current supplied via the power cord 71 of the MFP section 11. Meanwhile, the fixing heater 53 is turned on by the current supplied via the power cord 72 of the server section 12.

Note that, in this case, the power limitation needs to be completed before the earth leakage circuit breaker operates, and thus the time to start the power limitation needs to be set in consideration of the time to complete the power limitation after the start of the supply of power.

(b) In the case of the method of controlling the current flowing in the power cord 71 not to exceed 15 A

When the determiner 101 determines that the total current exceeds 15 A, the controller 103 performs the power limitation of the MFP section 11 as follows.

The controller 103 turns OFF the switch 114 to turn off the fixing heater 51, and turns ON the switch 115 to turn on the fixing heater 52. The fixing heater 52 is turned on by the current supplied via the power cord 71 of the MFP section 11.

Further, when receiving the start signal, the controller 103 turns the switch 116 ON to turn on the fixing heater 53. The fixing heater 53 is turned on by the current supplied via the power cord 72 of the server section 12.

(c) When the plug 72a is unplugged

When receiving the plug unplugged signal, and when the determiner 101 determines that the total current exceeds 15 A, the controller 103 performs the power limitation of the MFP section 11 as follows.

First, the controller 103 halves the process speed of image formation and the conveyance speed of the recording sheet of the MFP section 11 from the original speeds.

Secondly, the controller 103 turns OFF the switch 114 to turn off the fixing heater 51, and turns ON the switch 115 to turn on the fixing heater 52. Further, the switch 116 is turned OFF to turn off the fixing heater 53. The fixing heater 52 is turned on by the current supplied via the power cord 71 of the MFP section 11. In this case, the power consumption of the fixing heater is 300 W, and the power consumption is halved as compared with the case of turning on the fixing heater 51 (600 W).

In this manner, the process speed of image formation and the conveyance speed of the recording sheet in the MFP section 11 are halved from the original speeds, and the power consumption of the fixing heater is halved from the original power consumption. Therefore, in the fixer 50, the quantity of heat applied to the recording sheet is not changed, and the fixing property of the toner image on the recording sheet is maintained

The operation mode of this case is “scan to Copy” or “print” but limitation is imposed on the operation in the MFP section 11, and thus the operation mode is called limitation mode.

Note that, in this case, the power limitation needs to be completed before the earth leakage circuit breaker operates, and thus the time to start the power limitation needs to be set in consideration of the time to complete the power limitation after the start of the supply of power.

(Output of Message)

When receiving the failure signal and the plug unplugged signal, the controller 103 controls the operation panel 70 to display a failure message and a plug unplugged message. Here, the failure message indicates that the low-voltage power supply unit 211 of the server section 12 has broken down, and the plug unplugged message indicates that the plug 72a of the power cord 72 of the server section 12 is unplugged.

Further, when not receiving the failure signal, the plug unplugged signal, or any other error signal, the controller 103 controls the operation panel 70 to display a normal message. Here, the normal message indicates that the operations of the MFP section 11 and the server section 12 are normal. Note that when not receiving the failure signal, the plug unplugged signal, or any other error signal, the controller 103 may control the operation panel 70 not to display a special message.

(f) Communicator 104

The communicator 104 transmits and receives information between the server section 12 and the controller 103. Further, the communicator 104 transmits and receives information between an external device and the controller 103

(5) Fixing Heaters 51 to 53

Each of the fixing heaters 51, 52, and 53 is, for example, a halogen heater. The maximum rated power of the fixing heaters 51, 52, and 53 is, for example, 600 W, 300 W, and 300 W, respectively. Each of the fixing heaters 51, 52, and 53 is provided inside a tubular core metal of the heating roller 56.

The fixing heaters 51, 52, and 53 are connected to the switches 114, 115, and 116, respectively.

As described above, the fixing heaters 51, 52, and 53 are electrical loads.

(6) Operation Panel 70

The operation panel 70 is provided above the MFP section 11. The operation panel 70 includes a liquid crystal display panel and a touch pad.

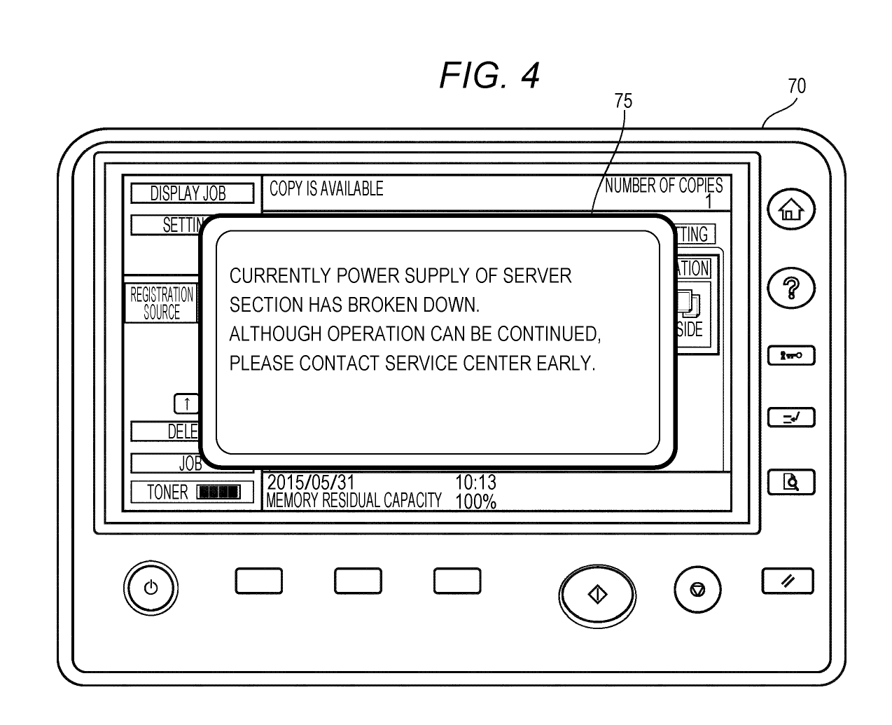

The operation panel 70 receives an instruction to start copying, setting of the number of copies, setting of copying conditions, and the like from a user, and notifies the received content to the MFP control board 100. Further, the operation panel 70 displays a copy mode and various messages set by the user. The message to be displayed includes a failure message 75 indicating that the low-voltage power supply unit of the server section 12 has broken down, as illustrated in FIG. 4, as an example. In addition, the message to be displayed includes the plug unplugged message indicating that the plug 72a of the power cord 72 of the server section 12 is unplugged. In addition, the message to be displayed includes the normal message indicating that the operations of the MFP section 11 and the server section 12 are normal.

1.2 Server Section 12

The server section 12 is a computer system that provides various services. The server section 12 is, for example, a print server, a mail server, a web server, a dynamic host configuration protocol (DHCP) server, a domain name system (DNS) server, or the like.

The print server is a control computer system used by a plurality of client computers arranged on a computer network when the MFP section 11 is used as a printer. When print requests are issued from a plurality of client computers, the print server appropriately processes these print requests and causes the MFP section 11 to execute printing.

The mail server is a computer system having a function to transfer electronic mails and receive electronic mails.

The WEB server is a computer system that provides display of HTML and objects (images, and the like) to a web browser of a client computer connected to a computer network according to the hypertext transfer protocol (HTTP).

The DHCP server is a computer system that automatically assigns setting information necessary for using a network such as an IP address to a client computer.

The DNS server is a computer system used for managing correspondence between a host name on the Internet or a domain name used for an electronic mail and IP address.

The server section 12 may provide services of virus check, system update, data backup, and various simulations in addition to the above service.

As illustrated in FIG. 2, the server section 12 includes the switch 214, the low-voltage power supply unit 211, a power supply system switching circuit (second switcher) 212, an uninterruptible power supply (UPS) device 213, and a control device (first electrical load) 200 that provides the above-described services and controls the server section 12. Here, the server section 12 may include a holder detachably holding the control device 200.

Power is supplied to the server section 12 from an external alternating-current power supply (commercial power supply) via the external outlet 72b, the plug 72a, and the power cord 72 through a power receiving path. The power receiving path connected to the external alternating-current power supply has a rated value (for example, 1500 W) that defines a maximum suppliable power. The power supplied from the outlet 72b via the power cord 72 is supplied to the control device 200 via the switch 214, the low-voltage power supply unit 211, the power supply system switching circuit 212, and the uninterruptible power supply device 213.

Note that, in the server section 12, the electrical parts and the electric circuits that consume power such as the switch 214, the low-voltage power supply unit 211, the power supply system switching circuit 212, the uninterruptible power supply device 213, and the control device 200 are electrical loads.

(1) Switch 214

The switch 214 switches connection between the power cord 72 and the low-voltage power supply unit 211 and connection between the power cord 72 and the power cord 118 by control of the control device 200.

Normally, the switch 214 connects the power cord 72 and the low-voltage power supply unit 211 by the control of the control device 200. The switch 214 switches the connection to the connection between the power cord 72 and the power cord 118 by the control of the control device 200 when an instruction is given from the MFP section 11. In this case, the power cord 72 is disconnected from the server section 12 and is connected to the MFP section 11.

(2) Low-Voltage Power Supply Unit 211

The low-voltage power supply unit 211 is connected to the outlet 72b via the plug 72a, the power cord 72, and the switch 214, and receives supply of alternating-current power from the outlet 72b.

The low-voltage power supply unit 211 includes a first detector (cord disconnection detector) 211a, a conversion circuit 211b, and a second detector (failure detector) 211c.

In the conversion circuit 211b, the direct current converted from the alternating current supplied from the outlet 72b has a voltage of 5 V (volts), for example. The conversion circuit 211b supplies the direct current to the power supply system switching circuit 212.

Each of the first detector 211a and the second detector 211c are normally operated by the direct current converted by the conversion circuit 211b. When the alternating current is not supplied via the plug 72a, the power cord 72, and the switch 214 or when the alternating current is not converted into the direct current due to the failure of the low-voltage power supply unit 211, the first detector 211a and the second detector 211c are operated by receiving the supply of the direct current from the uninterruptible power supply device 213.

The first detector 211a is, as an example, a voltage detection circuit that monitors the voltage of the alternating current supplied from the outlet 72b via the plug 72a, the power cord 72, and the switch 214. When no alternating current is supplied, it is determined that the plug 72a is unplugged, and the plug unplugged signal indicating that the plug 72a is unplugged is transmitted to the control device 200. When change in the alternating current falls within a predetermined range, it is determined that the plug 72a is not unplugged.

As an example, the second detector 211c monitors the direct-current voltage converted from the alternating current by the conversion circuit 211b, and determines whether the direct-current voltage falls within a predetermined range or whether the direct-current voltage is lower than a predetermined threshold. When the direct-current voltage falls within the predetermined range, it is determined that no failure has occurred in the low-voltage power supply unit 211. When the first detector 211a determines that the plug 72a is not unplugged and the second detector 211c determines that the direct-current voltage is lower than the predetermined threshold, it is determined that the failure has occurred in the low-voltage power supply unit 211. When it is determined that the failure has occurred in the low-voltage power supply unit 211, the failure signal indicating the occurrence of the failure in the low-voltage power supply unit 211 is transmitted to the control device 200.

Here, the current flowing in the power cord 72 connecting the outlet 72b and the low-voltage power supply unit 211 needs to be suppressed to equal to or less than 15 A that is the rated current of the power cord 72 (or equal to or less than 1500 W in power).

(3) Power Supply System Switching Circuit 212

The power supply system switching circuit 212 includes switches 215 and 216. The switch 215 switches connection/non-connection between the MFP section 11 and the uninterruptible power supply device 213 by the control of the control device 200. Further, the switch 216 switches connection/non-connection between the low-voltage power supply unit 211 and the uninterruptible power supply device 213 by the control of the control device 200.

When the switch 216 is ON, the direct current is supplied from the low-voltage power supply unit 211. Meanwhile, when the switch 216 is OFF, no direct current is supplied from the low-voltage power supply unit 211.

When the switch 215 is ON, the direct current is supplied from the DC power supply distribution circuit 112 of the MFP section 11. Meanwhile, when the switch 215 is OFF, no direct current is supplied from the MFP section 11.

That is, the power supply system switching circuit 212 outputs either the direct current supplied from the low-voltage power supply unit 211 or the direct current supplied from the DC power supply distribution circuit 112 of the MFP section 11 to the uninterruptible power supply device 213 by switching the switches 215 and 216 by the control of the control device 200.

(4) Uninterruptible Power Supply Device 213

The uninterruptible power supply device 213 includes a voltage detector 213a that detects the direct-current voltage supplied from the power supply system switching circuit 212 and a power storage 213b that stores the direct current supplied from the power supply system switching circuit 212.

The uninterruptible power supply device 213 stores the supplied direct current in the power storage 213b and supplies the direct current to the control device 200 at the normal time when the direct current is normally supplied from the power supply system switching circuit 212, that is, when the voltage detected by the voltage detector 213a falls within the predetermined range.

Further, the uninterruptible power supply device 213 supplies the direct current stored in the power storage 213b to the control device 200, the power supply system switching circuit 212, the low-voltage power supply unit 211, and the switch 214 in place of the direct current from the power supply system switching circuit 212, when the supply of the direct current from the power supply system switching circuit 212 is stopped, that is, when the voltage detected by the voltage detector 213a is lower than the predetermined threshold. Therefore, even when the supply of the direct current from the power supply system switching circuit 212 is stopped, the operation of the control device 200 can be continued as long as a power storage 213b.

(5) Control Device 200

The control device 200 includes a determiner 201, a calculator 202, a controller 203, a communicator 204, and a storage 205.

The control device 200 is called motherboard and specifically includes a CPU, a ROM, a RAM, a hard disk drive (HDD), a solid state drive (SSD), a redundant arrays of inexpensive disks or redundant arrays of independent disks (RAID) card, a network connection card, and the like. A control computer program is stored in the ROM, and the determiner 201, the calculator 202, and the controller 203 perform respective functions as the CPU is operated according to the control computer program. Further, the communicator 204 performs its function as the network connection card is operated. Further, the storage 205 includes a ROM and a RAM.

The communicator 204 is connected to the MFP section 11 via the LAN cable 119 and is connected to a LAN as an external network via another LAN cable.

(a) Storage 205

The storage 205 stores data necessary for the server section 12 to provide various services. Further, the storage 205 stores data necessary for controlling the server section 12.

(b) Determiner 201 and Calculator 202

The determiner 201 and the calculator 202 respectively perform determination and calculation necessary for the server section 12 to provide various services.

(c) Controller 203

When the second detector 211c has detected occurrence of the failure in the low-voltage power supply unit 211, the controller 203 transmits the failure signal indicating that the failure has occurred in the low-voltage power supply unit 211 of the server section 12 to the MFP section 11 via the communicator 204 and the LAN cable 119. Further, when the first detector 211a has detected that the plug 72a is unplugged, the controller 203 transmits the plug unplugged signal indicating that the plug 72a is unplugged to the MFP section 11 via the communicator 204 and the LAN cable 119.

Further, the controller 203 receives a request to supply power from the MFP section 11 via the LAN cable 119 and the communicator 204. When receiving the request to supply power, the controller 203 controls the switch 214 to switch the connection between the power cord 72 and the low-voltage power supply unit 211 to the connection between the power cord 72 and the MFP section 11. Further, the controller 203 transmits the start signal indicating that the supply of power has started from the power cord 72 to the MFP section 11, to the MFP section 11 via the communicator 204 and the LAN cable 119.

Further, the controller 203 performs necessary control when the server section 12 provides various services.

(d) Communicator 204

The communicator 204 transmits and receives information between the MFP section 11 and the controller 203. Further, the communicator 204 transmits and receives information between an external device and the controller 203

1.3 Operation of Image Forming System 10

Regarding the operation of the image forming system 10, the control method when the current flowing in the power cord 71 of the MFP section 11 temporarily exceeds 15 A, the control method when the current flowing in the power cord 71 of the MFP section 11 does not exceed 15 A, and the control method when the plug 72a of the power cord 72 of the server section 12 is unplugged will be described.

(1) The Control Method when the Current Temporarily Exceeds 15 A

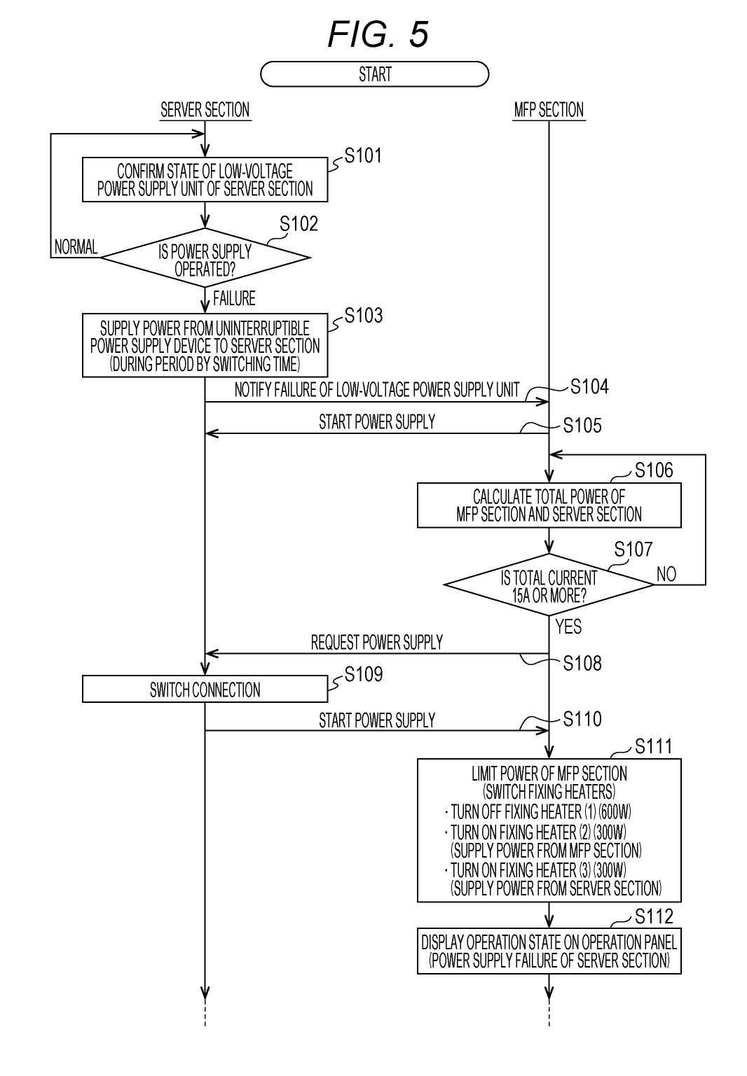

The control method when the failure has occurred in the low-voltage power supply unit 211 of the server section 12 and the current flowing in the power cord 71 of the MFP section 11 temporarily exceeds 15 A due to power supply from the MFP section 11 to the server section 12 will be described using the sequence diagram illustrated in FIG. 5.

The first detector 211a of the low-voltage power supply unit 211 of the server section 12 monitors whether the plug 72a is unplugged, and the second detector 211c monitors whether the failure has occurred in the low-voltage power supply unit 211 (step S101).

When the first detector 211a determines that the plug 72a is not unplugged and the second detector 211c determines that no failure has occurred in the low-voltage power supply unit 211 (“normal” in step S102), the controller 203 of the control device 200 returns the control to step S101 and repeats the processing.

When the first detector 211a determines that the plug 72a is not unplugged and the second detector 211c determines that the failure has occurred in the low-voltage power supply unit 211 (“failure” in step S102), the second detector 211c transmits the failure signal indicating that the failure has occurred, to the low-voltage power supply unit 211 to the control device 200. In this case, the uninterruptible power supply device 213 itself determines that the direct current is not normally supplied from the power supply system switching circuit 212, and supplies the direct current from the power storage 213b to the control device 200, the switch 214, the low-voltage power supply unit 211, and the power supply system switching circuit 212 of the server section 12 (step S103). A period in which the direct current is supplied from the power storage 213b to the constituent elements of the server section 12 is a period from a point of time when the failure of the low-voltage power supply unit 211 is found to a point of time when supply of the direct current from the MFP section 11 to the server section 12 is started.

The controller 203 of the control device 200 transmits the failure signal indicating that the failure has occurred in the low-voltage power supply unit 211 of the server section 12 to the MFP section 11 via the communicator 204 and the LAN cable 119. The controller 103 of the MFP control board 100 of the MFP section 11 receives the failure signal from the server section 12 via the LAN cable 119 and the communicator 104 (step S104).

When receiving the failure signal, the controller 103 controls the DC power supply distribution circuit 112 to supply the direct current to the server section 12, and the DC power supply distribution circuit 112 starts supply of the direct current to the server section 12 (step S105).

The calculator 102 of the MFP control board 100 calculates the total power consumption (total current) of the MFP section 11 and the server section 12 using the power table 300 stored in the storage 105 (step S106).

The determiner 101 determines whether the total current is 15 A or more (step S107). When the total current is determined not to be 15 A or more (“NO” in step S107), the controller 103 returns the control to step S106 and repeats the processing.

When the total current is determined to be 15 A or more (“YES” in step S107), the controller 103 requests the server section 12 to supply the power to the MFP section 11 via the communicator 104 and the LAN cable 119. The controller 203 receives the request to supply power from the MFP section 11 via the LAN cable 119 and the communicator 204 (step S108).

When receiving the request to supply power, the controller 203 controls the switch 214 to switch the connection between the power cord 72 and the low-voltage power supply unit 211 to the connection between the power cord 72 and the MFP section 11. The switch 214 switches the connection between the power cord 72 and the low-voltage power supply unit 211 to the connection between the power cord 72 and the MFP section 11 (step S109). The supply of power from the power cord 72 to the MFP section 11 is started. Further, the controller 203 transmits the start signal indicating that the supply of power has started from the power cord 72 to the MFP section 11, to the MFP section 11 via the communicator 204 and the LAN cable 119. The controller 103 receives the start signal from the server section 12 via the LAN cable 119 and the communicator 104 (step S110).

When receiving the start signal, the controller 103 performs power limitation of the MFP section 11. Specifically, the controller 103 turns OFF the switch 114 to turn off the fixing heater 51, and turns ON the switch 115 to turn on the fixing heater 52. Further, the controller 103 turns ON the switch 116 to turn on the fixing heater 53. The fixing heater 52 is turned on by the current supplied via the power cord 71 of the MFP section 11.

Meanwhile, the fixing heater 53 is turned on by the current supplied via the power cord 72 and the power cord 118 of the server section 12 (step S111).

The controller 103 controls the operation panel 70 to display the failure message indicating that the low-voltage power supply unit 211 of the server section 12 has broken down. The operation panel 70 displays the failure message (step S112).

The control when the current temporarily exceeds 15 A is terminated.

(Summary)

Here, for example, assuming that the operation mode of the MFP section 11 is “print”, and as illustrated in FIG. 3, the power necessary in the MFP section 11 is 1400 W and the power necessary in the server section 12 is 300 W.

In step S105, when the power is supplied from the MFP section 11 to the server section 12, the total current of the MFP section 11 and the server section 12 temporarily becomes 17 A (1700 W). The total current at this time exceeds the rated current of 15 A, but the total current (17 A) is 125% or less of the rated current 15 A. Further, in step S111, by switching the fixing heater to be turned on in the MFP section 11, the total power supplied from the power cord 71 of the MFP section 11 is reduced by 300 W to become 1400 W, and the total power supplied from the power cord 72 of the server section 12 becomes 300 W. As a result, both the power supplied from the power cord 71 of the MFP section 11 and the power supplied from the power cord 72 of the server section 12 do not exceed the rated value.

Further, since the thermal dose to the heating roller is 600 W in total including 300 W by the fixing heater 52 and 300 W by the fixing heater 53, and thus the thermal dose equivalent to 600 W by the fixing heater 51 can be maintained

(2) The Control Method when the Current Does Not Exceed 15 A

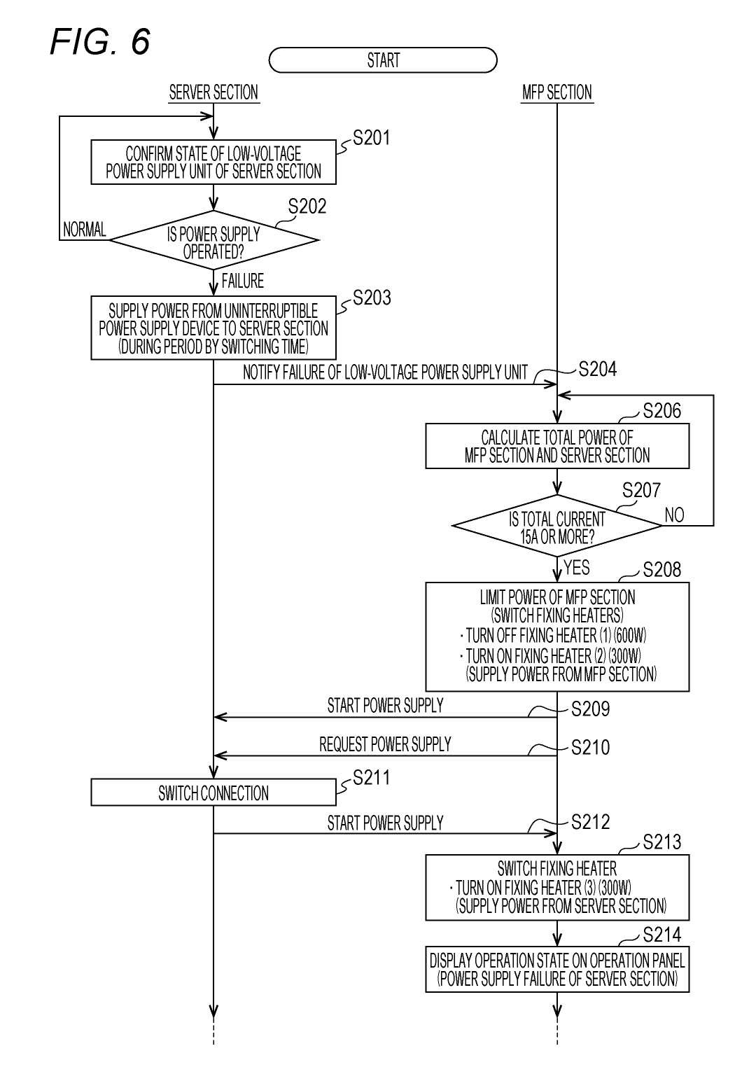

The method of controlling the current flowing in the power cord 71 of the MFP section 11 not to exceed 15 A due to the power supply from the MFP section 11 to the server section 12 when the failure has occurred in the low-voltage power supply unit 211 of the server section 12 will be described using the sequence diagram illustrated in FIG. 6.

The first detector 211a of the low-voltage power supply unit 211 of the server section 12 monitors whether the plug 72a is unplugged, and the second detector 211c monitors whether the failure has occurred in the low-voltage power supply unit 211 (step S201).

When the first detector 211a determines that the plug 72a is not unplugged and the second detector 211c determines that no failure has occurred in the low-voltage power supply unit 211 (“normal” in step S202), the controller 203 of the control device 200 returns the control to step S201 and repeats the processing.

When the first detector 211a determines that the plug 72a is not unplugged and the second detector 211c determines that the failure has occurred in the low-voltage power supply unit 211 (“failure” in step S202), the second detector 211c transmits the failure signal indicating that the failure has occurred, to the low-voltage power supply unit 211 to the control device 200. In this case, the uninterruptible power supply device 213 itself determines that the direct current is not normally supplied from the power supply system switching circuit 212, and supplies the direct current from the power storage 213b to the control device 200, the switch 214, the low-voltage power supply unit 211, and the power supply system switching circuit 212 of the server section 12 (step S203). A period in which the direct current is supplied from the power storage 213b to the constituent elements of the server section 12 is a period from a point of time when the failure of the low-voltage power supply unit 211 is found to a point of time when supply of the direct current from the MFP section 11 to the server section 12 is started.

The controller 203 of the control device 200 transmits the failure signal indicating that the failure has occurred in the low-voltage power supply unit 211 of the server section 12 to the MFP section 11 via the communicator 204 and the LAN cable 119. The controller 103 of the MFP control board 100 of the MFP section 11 receives the failure signal from the server section 12 via the LAN cable 119 and the communicator 104 (step S204).

When receiving the failure signal, the calculator 102 of the MFP control board 100 calculates the total power consumption (total current) of the MFP section 11 and the server section 12 using the power table 300 stored in the storage 105 (step S206).

The determiner 101 determines whether the total current is 15 A or more (step S207). When the total current is determined not to be 15 A or more (“NO” in step S207), the controller 103 returns the control to step S206 and repeats the processing.

When the total current is determined to be 15 A or more (“YES” in step S207), the controller 103 performs power limitation of the MFP section 11. Specifically, the controller 103 turns OFF the switch 114 to turn off the fixing heater 51, and turns ON the switch 115 to turn on the fixing heater 52. The fixing heater 52 is turned on by the current supplied via the power cord 71 of the MFP section 11 (step S208).

Next, the controller 103 controls the DC power supply distribution circuit 112 to supply the direct current to the server section 12, and the DC power supply distribution circuit 112 starts supply of the direct current to the server section 12 (step S209).

Next, the controller 103 requests the server section 12 to supply the power to the MFP section 11 via the communicator 104 and the LAN cable 119. The controller 203 receives the request to supply power from the MFP section 11 via the LAN cable 119 and the communicator 204 (step S210).

When receiving the request to supply power, the controller 203 controls the switch 214 to switch the connection between the power cord 72 and the low-voltage power supply unit 211 to the connection between the power cord 72 and the MFP section 11. The switch 214 switches the connection between the power cord 72 and the low-voltage power supply unit 211 to the connection between the power cord 72 and the MFP section 11 (step S211). The supply of power from the power cord 72 to the MFP section 11 is started. Further, the controller 203 transmits the start signal indicating that the supply of power has started from the power cord 72 to the MFP section 11, to the MFP section 11 via the communicator 204 and the LAN cable 119. The controller 103 receives the start signal from the server section 12 via the LAN cable 119 and the communicator 104 (step S212).

When receiving the start signal, the controller 103 turns the switch 116 ON to turn on the fixing heater 53. The fixing heater 53 is turned on by the current supplied via the power cord 72 of the server section 12 (step S213).

The controller 103 controls the operation panel 70 to display the failure message indicating that the low-voltage power supply unit 211 of the server section 12 has broken down. The operation panel 70 displays the failure message (step S214).

The control when the current does not exceed 15 A is terminated.

(Summary)

Here, for example, assuming that the operation mode of the MFP section 11 is “print”, and as illustrated in FIG. 3, the power necessary in the MFP section 11 is 1400 W and the power necessary in the server section 12 is 300 W.

In steps S207 and S208, when the total current of the MFP section 11 and the server section 12 is 15 A or more, the power consumption in the MFP section 11 is limited by switching the fixing heater from the fixing heater 51 (600 W) to the fixing heater 52 (300 W). At this time, the power consumption of the fixing heater is reduced by 300 W, the power of 1100 W is supplied from the power cord 71. Thereafter, in step S209, the power is supplied to the server section 12. At this time, the power necessary in the server section 12 is increased by 300 W, and the power supplied from the power cord 71 is changed from 1100 W to 1400 W. Next, in steps S211 to S213, the power is supplied from the power cord 72 of the server section 12 to the MFP section 11, and the total power supplied from the power cord 72 of the server section 12 becomes 300 W. As a result, both the power supplied from the power cord 71 of the MFP section 11 and the power supplied from the power cord 72 of the server section 12 do not exceed the rated value.

Further, since the thermal dose to the heating roller is 600 W in total including 300 W by the fixing heater 52 and 300 W by the fixing heater 53, and thus the thermal dose equivalent to 600 W by the fixing heater 51 can be maintained

(3) The Control Method when the Power Cord of the Server Section is Disconnected

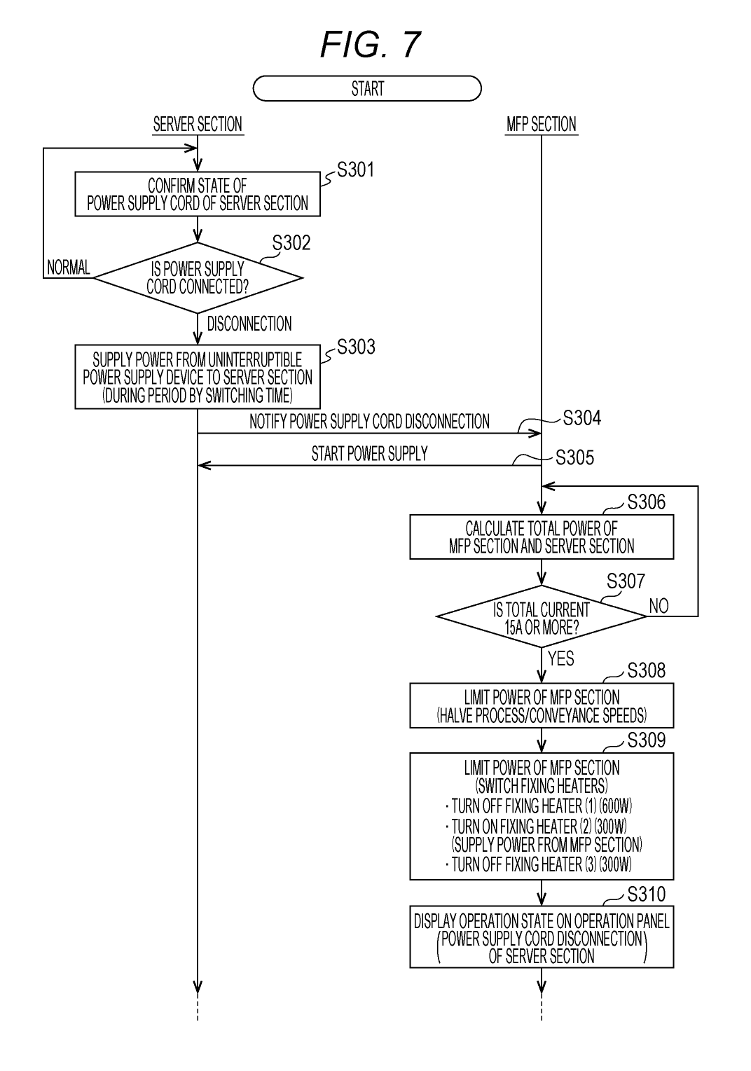

The control method when the plug 72a of the power cord 72 of the server section 12 is unplugged will be described using the sequence diagram illustrated in FIG. 7.

The first detector 211a of the low-voltage power supply unit 211 of the server section 12 monitors whether the plug 72a is unplugged, and the second detector 211c monitors whether the failure has occurred in the low-voltage power supply unit 211 (step S301). When the first detector 211a determines that the plug 72a is not unplugged (“normal” in step S302), the controller 203 of the control device 200 returns the control to step S301 and repeats the processing.

When the first detector 211a detects that the plug 72a is unplugged (“disconnection” in step S302), the first detector 211a transmits the plug unplugged signal indicating that the plug 72a is unplugged to the control device 200. In this case, the uninterruptible power supply device 213 itself determines that the direct current is not normally supplied from the power supply system switching circuit 212, and supplies the direct current from the power storage 213b to the control device 200, the switch 214, the low-voltage power supply unit 211, and the power supply system switching circuit 212 of the server section 12 (step S303). A period in which the direct current is supplied from the power storage 213b to the constituent elements of the server section 12 is a period from a point of time when the plug 72a being unplugged is detected to a point of time when supply of the direct current from the MFP section 11 to the server section 12 is started.

The controller 203 of the control device 200 transmits the plug unplugged signal indicating that the plug 72a is unplugged to the MFP section 11 via the communicator 204 and the LAN cable 119. The controller 103 of the MFP control board 100 of the MFP section 11 receives the plug unplugged signal from the server section 12 via the LAN cable 119 and the communicator 104 (step S304).

When receiving the plug unplugged signal, the controller 103 controls the DC power supply distribution circuit 112 to supply the direct current to the server section 12, and the DC power supply distribution circuit 112 starts supply of the direct current to the server section 12 (step S305).

The calculator 102 of the MFP control board 100 calculates the total power consumption (total current) of the MFP section 11 and the server section 12 using the power table 300 stored in the storage 105 (step S306).

The determiner 101 determines whether the total current is 15 A or more (step S307). When the total current is determined not to be 15 A or more (“NO” in step S307), the controller 103 returns the control to step S306 and repeats the processing.

When the total current is determined to be 15 A or more (“YES” in step S307), the controller 103 performs power limitation of the MFP section 11. Specifically, first, the controller 103 halves the process speed of image formation and the conveyance speed of the MFP section 11 from the original speeds (step S308). Secondly, the controller 103 turns OFF the switch 114 to turn off the fixing heater 51, turns ON the switch 115 to turn on the fixing heater 52, and turns OFF the switch 116 to turn off the fixing heater 53. The fixing heater 52 is turned on by the current supplied via the power cord 71 of the MFP section 11 (step S309).

The controller 103 controls the operation panel 70 to display the plug unplugged message indicating that the plug 72a of the power cord 72 of the server section 12 is unplugged. The operation panel 70 displays the plug unplugged message (step S310).

The control when the plug 72a of the power cord 72 of the server section 12 is unplugged is terminated.

(Summary)

Here, for example, assuming that the operation mode of the MFP section 11 is “print”, and as illustrated in FIG. 3, the power necessary in the MFP section 11 is 1400 W and the power necessary in the server section 12 is 300 W.

When the plug 72a of the power cord 72 of the server section 12 is unplugged, the power is supplied from the MFP section 11 to the server section 12 in step S305. At this time, the power supplied from the power cord 71 is 1700 W. Since the total current of the MFP section 11 and the server section 12 is 15 A or more, the fixing heater to be turned on is switched in the MFP section 11 in step S309. At this time, the total power supplied from the power cord 71 is decreased by 300 W due to switching of the fixing heater and becomes 1400 W. As a result, the power supplied from the power cord 71 of the MFP section 11 does not exceed the rated value.

In addition, since the thermal dose to the heating roller is 300 W by the fixing heater 52, the thermal dose of half of 600 W by the fixing heater 51 is maintained. At this time, since the process speed of image formation and the conveyance speed of the MFP section 11 are halved from the original speeds, the fixing property of the toner image on the recording sheet can be maintained

2. Supplementary Description of the Embodiment and Other Modifications

The above embodiment will be supplementarily described, and other modifications will be described.

(1) When the failure has been detected in the low-voltage power supply unit 211, the controller 103 may calculate first power consumption in the electrical load held by the server section 12, determine whether the power supplied to the second power cord 71 exceeds the rated value on the basis of the calculated first power consumption, and determine whether to request the server section 12 to supply power according to a determination result.

When the failure has been detected in the low-voltage power supply unit 211, the controller 103 may further calculate second power consumption in the electrical load held by the MFP section 11, adds the first power consumption and the second power consumption to calculate an input current to be supplied from the outlet 71b, determine whether the calculated input current exceeds the rated value, and request the server section 12 to supply power when the calculated input current exceeds the rated value, and may block the request to the server section 12 to supply power when the calculated input current does not exceed the rated value.

When the failure has been detected in the low-voltage power supply unit 211, the controller 103 may determine whether the input power to be supplied from the outlet 71b of the MFP section 11 exceeds the rated value by prediction, assuming that part of output power from the DC power supply distribution circuit 112 is supplied to the server section 12. In this case, when the input power from the outlet 71b is determined to exceed the rated value, the DC power supply distribution circuit 112 may start supply of the part of the output power to the server section 12 before actual input power supplied from the outlet 71b exceeds the rated value.

Even when the current flowing in the power cord 71 of the MFP section 11 temporarily exceeds the rated value (15 A), the problem that the earth leakage circuit breaker operates does not occur as long as the current falls within the conformity criteria of the earth leakage circuit breaker.

(2) The controller 103 may calculate the first power consumption necessary in the server section 12 from an operation status of the server section 12.

Further, the server section 12 may be a server having a function to periodically perform data processing, for example, once a day. At periodic data processing timing of the server section 12, the controller 103 calculates the first power consumption necessary in the server section 12 at that timing.

(3) When part of the supply of power to the fixing heater as the electrical load held by the MFP section 11 is switched to the supply of power from the outlet 72b by the power supply system switching circuit 113, the switching may be performed during time from a point of time when the input power from the outlet 71b exceeds the rated value to a point of time when a circuit breaker arranged on the power path to the outlet 71b is predicted to cut off overcurrent.

(4) When the failure has been detected in the low-voltage power supply unit 211, whether to decrease the power consumption of the electrical load held by the MFP section 11 may be determined according to whether the input power supplied from the outlet 71b satisfies part rating of electrical parts (for example, a power supply cable and a connector) included in the MFP section 11. Further, when the failure has been detected in the low-voltage power supply unit 211, and in the case where the total power consumption obtained by adding the power consumption in the electrical load (for example, the control device 200) held by the server section 12, and the second power consumption determined according to the operation mode (such as “sleeping”, “standby”, “scan to Server”, “scan to Copy”, or “print”) of the MFP section 11 in the electrical load (for example, the fixing heaters 51, 52, and 53) held by the MFP section 11 exceeds the rated value, the controller 103 may determine whether to decrease the power consumption of the electrical load held by the MFP section 11 (for example, whether to turn off the fixing heater 51 of 600 W and to turn on the fixing heater 52 of 300 W) according to the operation state of the MFP section 11.

(5) The MFP section 11 may be operated in any of the operation modes of the first operation mode and the second operation mode. The first operation mode is the operation mode (such as “sleeping”, “standby”, or “scan to Server”) in the case where the power consumption of the electrical load (for example, the fixing heaters 51, 52, and 53) held in the MFP section 11 is determined not to be decreased. The second operation mode is the operation mode (such as “scan to Copy” or “print”) in the case where the power consumption of the electrical load held by the MFP section 11 is determined to be decreased.

When the failure has been detected in the low-voltage power supply unit 211, the controller 103 may determine whether the operation mode of the MFP section 11 is the first operation mode or the second operation mode. In the first operation mode, the controller 103 blocks the request to the server section 12 to supply power. On the other hand, in the second operation mode, the controller 103 requests the server section 12 to supply power.

(6) When the power is not normally supplied from the low-voltage power supply unit 211 and the total power consumption in the MFP section 11 and the server section 12 exceeds the rated value due to supply of the power from the MFP section 11 to the server section 12, the MFP section 11 can reduce the power to be supplied to the fixing heater.

In such a case, the process speed of image formation and the conveyance speed of the recording sheet in the MFP section 11 may be halved from the original speeds, and the power consumption of the fixing heater may be halved from the original power consumption. In this case, in the fixer 50, the quantity of heat applied to the recording sheet is not changed, and the fixing property of the toner image on the recording sheet is maintained

In this manner, the operation mode of the MFP section 11 is restrictedly changed according to the suppliable power to the electrical load of the MFP section 11. Here, the operation mode is a mode to operate at a normal speed of the process of image formation and a normal conveyance speed of the recording sheet in the MFP section 11, and a mode to operate at speeds half of the normal speeds (a speed half the speed of the process of image formation and a speed half the conveyance speed of the recording sheet).

(7) The MFP section 11 may include a plurality of power cords (second power receiving members), and the server section 12 may include a plurality of power cords (first power receiving members). The electrical load (for example, the fixing heaters 51 and 52) held by the MFP section 11 may be connected to the outlet 71b by a plurality of power cords, and the electrical load (for example, the control device 200) held by the server section 12 may be connected to the outlet 72b by a plurality of power cords. Each of the electrical loads of the MFP section 11 and the server section 12 is supplied power via at least one power cord even when the number of power cords connected to the outlet is changed, that is, even in a state where a part of the plurality of power cords is pulled out from the outlet.

Here, the controller 103 may control whether to supply power to the electrical loads respectively held by the MFP section 11 and the server section 12 according to the numbers of the power cords connected to the outlets 71b and 72b.

For example, regarding the electrical load of the MFP section 11, in a case where two power cords are connected to the outlet and the power consumption of the electrical load of the MFP section 11 is 2000 W, for example, exceeding 1500 W, the power supply to the electrical load of the MFP section 11 may be continued from the two power cords by 1000 W each.

Meanwhile, regarding the electrical load of the MFP section 11, in a case where only one power cord is connected to the outlet and the power consumption of the electrical load of the MFP section 11 is 2000 W, for example, exceeding 1500 W, the power supply to the electrical load of the MFP section 11 by the one power cord is stopped, or the power consumption in the electrical load of the MFP section 11 is controlled to become 1500 W or less. In this case, regarding the electrical load of the server section 12, at least one power cord is connected to the outlet, and if the electrical load of the MFP section 11 can receive the power supply via the electrical cord of the server section 12, the power may be supplied to the electrical load of the MFP section 11 and the electrical load of the server section 12 to keep the power of the power cords 1500 W or less.

(8) As described in the embodiment, the uninterruptible power supply device 213 having the function to hold the power output for a fixed time when the low-voltage power supply unit 211 does not normally output the direct current is connected to the low-voltage power supply unit 211 of the server section 12. Here, the low-voltage power supply unit 211 may have the function to hold the power output for a fixed time when not normally outputting the direct current, instead of being connected to the uninterruptible power supply device 213.

(9) As described in the embodiment, the server section 12 and the MFP section 11 are connected by the communication line (LAN cable 119). The server section 12 and the MFP section 11 may transmit and receive information including operation state information indicating respective operation states via the communication line.

(10) As described in the embodiment, each of the outlet 71b and the outlet 72b supplies the alternating-current power. The alternating-current power is supplied to the low-voltage power supply unit 111 and the low-voltage power supply unit 211 from the outlet 71b and the outlet 72b. The low-voltage power supply unit 111 and the low-voltage power supply unit 211 convert the alternating current to generate the direct current.

When the failure has occurred in the low-voltage power supply unit 211, the DC power supply distribution circuit 112 supplies the direct current to the server section 12 by the control of the controller 103. Meanwhile, the alternating current is supplied from the outlet 72b to the MFP section 11.

Further, when the power cord 72 is unplugged from the outlet 72b, the DC power supply distribution circuit 112 supplies the direct current to the server section 12 by the control of the controller 103.

(11) As described in the embodiment, the MFP section 11 includes the fixer 50 that fixes the toner image on the recording sheet by heating and pressurization by the heating roller 56 and the pressure roller 55. The heating roller 56 is the electrical load in the MFP section 11.

When the failure has been detected in the low-voltage power supply unit 211 of the server section 12, the controller 103 may determine whether to supply the power from the outlet 72b to the MFP section 11 according to whether the operation mode is the operation mode to fix the toner image on the recording sheet (for example, the operation mode “scan to Copy” or “print”) using the fixer 50. Here, in the operation mode to fix the toner image on the recording sheet, the controller 103 determines that the power is to be supplied from the outlet 72b to the MFP section 11. When the operation mode is not the operation mode to fix the toner image on the recording sheet, the controller 103 determines that the power is not to be supplied from the outlet 72b to the MFP section 11.

(12) The calculator 102 may calculate the power necessary in the MFP section 11 according to the number of prints or a printing rate in each recording sheet in the MFP section 11. The determiner 101 may determine whether the power becomes insufficient and when the power becomes insufficient, the controller 103 may perform the image forming process and the conveyance of the recording sheet at lower speeds than the normal speed of the image forming process and the normal conveyance speed of the recording sheet.

(13) The problem pointed out in the above “Description of the Related art” is not limited to the apparatus in which the image forming device and the server device are integrated. For example, the problem also occurs in a system (equipment) including an image forming device and another unit such as a post-processing device or a paper feeding device.

As described in the above-described embodiment, the image forming system 10 is the apparatus in which the server section 12 and the MFP section 11 are integrated. However, the image forming system may include another unit in place of the server section 12 in order to solve the problem caused in the system including an image forming device and another unit such as a post-processing device or a paper feeding device. Here, the another unit is, for example, a post-processing device or a paper feeding device. That is, the image forming system is constituted by the image forming device and the another unit.

The image forming device is connected to an external first outlet by a power cord and a plug, and includes an image reader, a printer, a sheet feeder, a switch, a low-voltage power supply unit, a power supply system switching circuit, an uninterruptible power supply device, and the like. Here, the switch, the low-voltage power supply unit, the power supply system switching circuit, and the uninterruptible power supply device have the same configurations as the switch 214, the low-voltage power supply unit 211, the power supply system switching circuit 212, and the uninterruptible power supply device 213 included in the server section 12.

Further, the another unit is connected to an external second outlet by a power cord and a plug, and includes a post-processor that performs post-processing and the like, a low-voltage power supply unit, a DC power supply distribution circuit, a power supply system switching circuit, and the like. Here, the low-voltage power supply unit, the DC power supply distribution circuit, and the power supply system switching circuit have the same configurations as the low-voltage power supply unit 111, the DC power supply distribution circuit 112, and the power supply system switching circuit 113 included in the MFP section 11.

Each of the image forming device and the another unit has an electrical load.

When a failure occurs in the low-voltage power supply unit included in the image forming device or when the power cord included in the image forming device is not connected to the outlet, the image forming system including the image forming device and the another unit is similarly operated to the image forming system 10 in the above-described embodiment. When the failure has occurred in the low-voltage power supply unit included in the image forming device, the another unit supplies a direct current to the image forming device. When a current supplied from the external second outlet on the another unit side exceeds a rated value, the another unit receives supply of power from the external first outlet on the image forming device side. The another unit switches part of the supply of power to the electrical load held by the another unit to the supply of power from the external first outlet on the image forming device side.

When the power cord included in the image forming device is not connected to the outlet, the another unit supplies a direct current and an alternating current to the image forming device. When the current supplied from the outlet of the another unit exceeds the rated value, the another unit performs control to limit power consumption of the electrical load held by the another unit.

With this configuration, the above problem can be solved.

(14) In the above-described embodiment, the MFP control board 100 of the MFP section 11 stores the power table, calculates the total power in the MFP section 11 and the server section 12, and determines whether the total power exceeds 15 A. However, the embodiment is not limited to the configuration.

The control device 200 of the server section 12 may store the power table, and the control device 200 may calculate the total power in the MFP section 11 and the server section 12 and determine whether the total power exceeds 15 A. The server section 12 requests the MFP section 11 to supply the direct current, and the server section 12 receives the supply of the direct current from the MFP section 11. Further, the server section 12 supplies the alternating current to the MFP section 11.

(15) In the above-described embodiment, the power limitation of the MFP section 11 is performed as follows.

In the case of the method of controlling the current flowing in the power cord 71 to temporarily exceed 15 A, or in the case of the method of controlling the current flowing in the power cord 71 not to exceed 15A, the controller 103 turns off the fixing heater 51 and turns on the fixing heaters 52 and 53. The fixing heater 52 is turned on by the current supplied from the outlet 71b via the power cord 71 of the MFP section 11. Meanwhile, the fixing heater 53 is turned on by the current supplied from the outlet 72b via the power cord 72 of the server section 12. However, the embodiment is not limited to the configuration.

The controller 103 may turn on the fixing heater 51 and turn off the fixing heater 52 and the fixing heater 53. In this case, the fixing heater 51 is turned on by the current supplied from the outlet 72b via the power cord 72 of the server section 12. Further, the current may be supplied from the outlet 72b to the electrical load other than the fixing heaters of the MFP section 11, such as the operation panel or the image forming units 28Y, 28M, 28C, and 28K, via the power cord 72 of the server section 12.

(16) A refrigerator system (information processing apparatus) 10A as a modification according to the present invention will be described with reference to the drawings.

The refrigerator system 10A is an apparatus in which a refrigerator (second device) 11A and a server section (first device) 12A are integrated.

The refrigerator system 10A is installed in a home. The refrigerator 11A is used for freezing and refrigerating foods such as fresh foods. The server section 12A is connected to household electrical appliances such as a digital broadcast receiving device, a recording medium reproducing device, a lighting device, a cooling device, and a heating device installed in the home via a home LAN (not illustrated), and controls operations of these household electrical appliances. In addition, the server section 12A acquires data and control programs related to the operations of the household electrical appliances from the outside, installs the acquired data and control programs in the household electrical appliances, and updates the household electrical appliances.

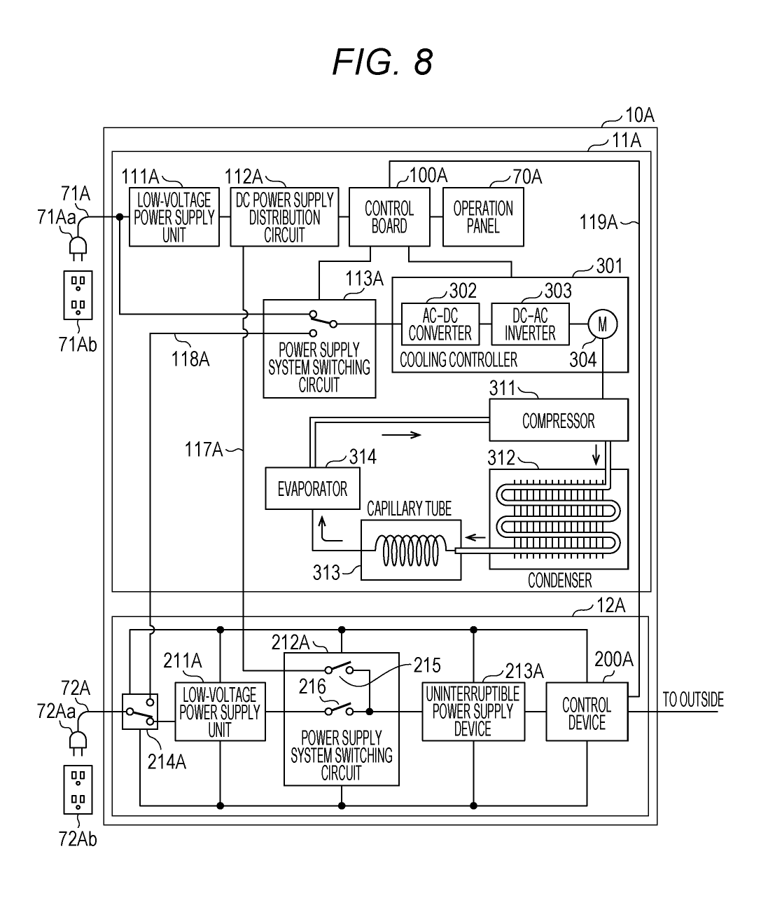

FIG. 8 is a diagram illustrating a detailed configuration regarding a power system and the like in the refrigerator system 10A.

As illustrated in FIG. 8, the refrigerator 11 A includes a cooling controller 301, a compressor 311, a condenser 312, a capillary tube 313, and an evaporator 314. The cooling controller 301 includes an AC-DC converter 302, a DC-AC inverter 303, and a motor 304.

The compressor 311 compresses a refrigerant gas. The condenser 312 releases the heat of the refrigerant gas at high temperature and high pressure to liquefy the refrigerant gas. The liquefied refrigerant is sent to the evaporator 314 through the capillary tube 313. In the evaporator 314, the pressure of the refrigerant is suddenly lowered, the refrigerant vaporizes, takes away heat from the surroundings, cools the interior of the refrigerator 11A, and the refrigerant that has become a gas is again sent to the compressor 311.

The AC-DC converter 302 converts an alternating current into a direct current. The DC-AC inverter 303 converts a direct current into an alternating current. The motor 304 is rotated by the direct current and transmits rotational driving force to the compressor 311.

The refrigerator 11A further includes a low-voltage power supply unit (second power supply circuit) 111A, a DC power supply distribution circuit (distributor) 112A, a control board 100A, an operation panel 70A, and a power supply system switching circuit (third switcher) 113A. Power is supplied to the refrigerator 11A from an outlet 71Ab via a plug 71Aa and a power cord 71A. The power supplied via the power cord 71A is supplied to the cooling controller 301 via the power supply system switching circuit 113A. The alternating current supplied via the power cord 71A is converted into a direct current by the low-voltage power supply unit 111A and is supplied to constituent elements of the server section 12A and the refrigerator 11A via the DC power supply distribution circuit 112A.

The control board 100A has a similar configuration to the MFP control board 100, and controls the cooling controller 301 to set the temperature inside the refrigerator 11 A to be a target temperature. Further, the control board 100A performs other control in the refrigerator 11A. The operation panel 70A displays a state in the refrigerator 11A and receives an operation from a user.

The low-voltage power supply unit 111A, the DC power supply distribution circuit 112A, and the power supply system switching circuit 113A have similar configurations to the low-voltage power supply unit 111, the DC power supply distribution circuit 112, and the power supply system switching circuit 113 of the MFP section 11 of the above embodiment.

Further, the server section 12A includes a switch (first switcher) 214A, a low-voltage power supply unit (first power supply circuit) 211A, a power supply system switching circuit 212A, an uninterruptible power supply device 213A, and a control device 200A that provides the aforementioned services and controls the server section 12A.

Power is supplied from an outlet (first external power supply) 72Ab to the server section 12A via a plug 72Aa and a power cord 72A. The power supplied from the outlet 72Ab via the power cord 72A is supplied to the control device 200A via the switch 214A, the low-voltage power supply unit 211A, the power supply system switching circuit 212A, and the uninterruptible power supply device 213A.

The switch 214A, the low-voltage power supply unit 211A, the power supply system switching circuit 212A, the uninterruptible power supply device 213A, and the control device 200A respectively have similar configurations to the switch 214, the low-voltage power supply unit 211, the power system switching circuit 212, the uninterruptible power supply device 213, and the control device 200 of the server section 12 of the above-described embodiment.

The refrigerator system 10A is similarly operated to the image forming system 10 of the above-described embodiment when the low-voltage power supply unit 211A of the server section 12A is not normally operated.

When a failure has occurred in the low-voltage power supply unit 211A, the refrigerator 11A supplies the direct current to the server section 12A. The server section 12A is operated by the direct current supplied from the refrigerator 11A. In the case where a current flowing in the power cord 71A exceeds a rated value, the refrigerator 11A receives supply of an alternating current from the power cord 72A of the server section 12A in place of the alternating current supplied from the power cord 71A, and the cooling controller 301 is operated by the supplied alternating current.

When the plug 72Aa is unplugged, the refrigerator 11A supplies the direct current to the server section 12A. The server section 12A is operated by the direct current supplied from the refrigerator 11A. When the current flowing in the power cord 71A exceeds the rated value, the refrigerator 11A controls the cooling controller 301 to rise the target temperature inside the refrigerator to decrease the power consumed in the cooling controller 301 so that the current flowing in the power cord 71A does not exceed the rated value

(Modification)

Here, the refrigerator system 10A may include a digital broadcast receiving and recording device (first device, not illustrated) instead of the server section 12A. A refrigerator (second device) 11A and a digital broadcast receiving and recording device are integrally configured.

The digital broadcast receiving and recording device receives digital broadcast, extracts a program from the received digital broadcast, and records the extracted program on a built-in hard disk. The digital broadcast receiving and recording device is connected to a digital broadcast reproducing device installed in a home via a home LAN. The digital broadcast receiving and recording device transmits the recorded program to the digital broadcast reproducing device at the request of the digital broadcast reproducing device, the digital broadcast reproducing device receives the program, reproduces the received program, and outputs the program as sounds and images.

Here, the digital broadcast receiving and recording device records all programs of all channels receivable over a long period of time, for example, over a month, on the built-in hard disk. Even when the user misses a program broadcasted in real time, the digital broadcast receiving and recording device records all the programs of all the channels receivable over a month, for example, and thus the user can watch the desired program.

Since the digital broadcast receiving and recording device needs to be continuously operated for a long time, the digital broadcast receiving and recording device includes a switch, a low-voltage power supply unit, a power supply system switching circuit, and an uninterruptible power supply device. Here, the switch, the low-voltage power supply unit, the power supply system switching circuit, and the uninterruptible power supply device have similar configurations to the switch 214A, the low-voltage power supply unit 211A, the power supply system switching circuit 212A, and the uninterruptible power supply device 213A included in the server section 12A. The digital broadcast receiving and recording device receives supply of power from an outlet via a plug and a power cord.

When a failure occurs in the low-voltage power supply unit of the digital broadcast receiving and recording device and when the plug of the digital broadcast receiving and recording device is unplugged, the refrigerator 11A and the digital broadcast receiving and recording device are similarly operated to the refrigerator system 10A.

(17) In the above-described embodiment, the MFP section 11 includes the fixing heaters 52 and 53. The fixing heaters 52 and 53 are connected to the switches 115 and 116, respectively. However, the embodiment is not limited to the configuration.

The MFP section 11 may include a fixing heater of 300 W similar to the fixing heater 52 and a switch in place of the fixing heaters 52 and 53 and the switches 115 and 116. This switch switches connection/non-connection between the fixing heater and the power cord 71 and connection/non-connection between the fixing heater and a power cord 118 by control of the MFP control board 100.

(18) In the above-described embodiment, the low-voltage power supply unit 211 includes the second detector 211c for detecting a failure in the low-voltage power supply unit 211. However, the embodiment is not limited to the configuration.

The power supply system switching circuit 212 may include a failure detector for detecting a failure in the low-voltage power supply unit 211 in place of the low-voltage power supply unit 211 including the second detector 211c.

(19) In the above-described embodiment, the control device 200 switches on and off the switches 215 and 216 of the power supply system switching circuit 212. However, the embodiment is not limited to the configuration.

The uninterruptible power supply device 213 may switch on and off the switches 215 and 216 of the power supply system switching circuit 212.

(20) In the above-described embodiment, as illustrated in steps S107 to S111 of FIG. 5, when the total current is determined to be 15 A or more, the controller 103 requests the server section 12 to supply power to the MFP section 11, and the power is supplied from the server section 12 to the MFP section 11 via the power cord 118. At this time, the controller 103 receives the start signal from the server section 12, and when receiving the start signal, the controller 103 switches the fixing heater.

However, the embodiment is not limited to the configuration.

For example, in the case where execution of a plurality of print jobs is continuously executed in the MFP section 11, the controller 103 may switch the fixing heater at the break between the print job and the print job after receiving the start signal from the server section 12.

(21) The present invention may be the above-described method. Further, these methods may be computer programs realized by a computer. Here, the computer program is configured by combining a plurality of instruction codes indicating commands to the computer in order to achieve a predetermined function.

Further, the present invention may be a computer program recorded in a computer-readable recording medium, for example, a flexible disk, a hard disk, an optical disk, a semiconductor memory, or the like. Further, the present invention may be a computer program recorded on these recording media.

Further, the present invention may be a computer system including a microprocessor and a memory, and the memory may store a computer program and the microprocessor may be operated according to the computer program.

(22) The above embodiments and modifications may be combined.

The information processing apparatus according to the present invention exhibits an effect to continue the operations of the first device and the second device even when the power supply unit of the first device does not normally output the power, and is useful as a technology capable of stably supplying power to an electrical load.

Although embodiments of the present invention have been described and illustrated in detail, the disclosed embodiments are made for purposes of illustration and example only and not limitation. The scope of the present invention should be interpreted by terms of the appended claims

What is claimed is:

1. An information processing apparatus including a first device and a second device,
the first device comprising a first power receiving member, a first switcher, a first power supply circuit, a failure detector, a second switcher, and a first electrical load,
the second device comprising a second power receiving member, a second power supply circuit, a distributor, a third switcher, a second electrical load, and a hardware processor, wherein
the first switcher switches connection between the first power receiving member connected to an external power supply and the first power supply circuit to connection between the first power receiving member and the third switcher by a request of the second device,
the first power supply circuit converts power supplied via the first power receiving member to generate first output power in a case where the first power supply circuit is connected to the first power receiving member by the first switcher,
the failure detector detects a failure in the first power supply circuit, and notifies the second device of detection of the failure when the failure detector has detected the failure,
the second switcher switches connection between the first power supply circuit and the first electrical load to connection between the distributor and the first electrical load when the failure has been detected,
the first electrical load receives supply of the first output power from the first power supply circuit, and receives supply of power from the distributor when the failure has been detected,
the second power supply circuit and the third switcher are connected to the external power supply via the second power receiving member and a power receiving path having a rated value that defines a maximum suppliable power,
the second power supply circuit converts supplied power to generate second output power,
the distributor supplies part of the second output power to the second switcher when the failure has been notified,
the third switcher switches connection between the second power receiving member and the second electrical load to connection between the second power receiving member and a part of the second electrical load and connection between the first switcher and a remaining part of the second electrical load when the failure has been notified,
the second electrical load receives supply of power via the second power receiving member, and the part of the second electrical load receives supply of power via the second power receiving member and the remaining part of the second electrical load receives supply of power via the first power receiving member when the failure has been detected, and
the hardware processor requests the first device to supply power when the power supplied via the second power receiving member exceeds the rated value due to the supply of power to the second switcher by the distributor.

2. The information processing apparatus according to claim 1, wherein,
when the failure has been detected in the first power supply circuit, the hardware processor calculates first power consumption in the first electrical load, determines whether the power supplied via the second power receiving member exceeds the rated value on the basis of the calculated first power consumption, and determines whether to request the first device to supply power according to a determination result.

3. The information processing apparatus according to claim 2, wherein,
when the failure has been detected in the first power supply circuit, the hardware processor calculates second power consumption in the second electrical load, adds the first power consumption and the second power consumption to calculate the power supplied via the second power receiving member, determines whether the calculated power exceeds the rated value, and requests the first device to supply power when the calculated power exceeds the rated value, and blocks the request to the first device to supply power when the calculated power does not exceed the rated value.

4. The information processing apparatus according to claim 1, wherein,
when the failure has been detected in the first power supply circuit, the hardware processor determines whether power to be supplied via the second power receiving member exceeds the rated value by prediction when part of the second output power generated by the second power supply circuit is assumed to be supplied to the first device, and
when the power to be supplied via the second power receiving member is determined to exceed the rated value, the distributor starts supply of the part of the second output power generated by the second power supply circuit to the first device before actual power supplied via the second power receiving member exceeds the rated value.

5. The information processing apparatus according to claim 2, wherein
the hardware processor calculates the first power consumption in the first device from an operation status of the first device.

6. The information processing apparatus according to claim 5, wherein
the first device is a server having a function to periodically perform data processing, and
the hardware processor calculates the first power consumption necessary at timing of the periodic data processing by the first device.

7. The information processing apparatus according to claim 1, wherein
the switching of connection by the third switcher is performed during time from a point of time when the power supplied via the second power receiving member exceeds the rated value to a point of time when a circuit breaker disposed on a power path from the external power supply to the second power receiving member is predicted to cut off an overcurrent.

8. The information processing apparatus according to claim 1, wherein,
when the failure has been detected in the first power supply circuit, the hardware processor further determine whether power to be supplied via the second power receiving member satisfies a part rating of an electrical part included in the second device when part of the second output power generated by the second power supply circuit is assumed to be supplied to the first device, and determines whether to decrease power consumption of the electrical load held by the second device according to a determination result.

9. The information processing apparatus according to claim 1, wherein,
when the failure has been detected in the first power supply circuit and the input power supplied via the second power receiving member exceeds the rated value, the hardware processor determines whether to decrease power consumption of the electrical load held by the second device according to an operation mode of the second device.

10. The information processing apparatus according to claim 9, wherein
the second device is operated in the operation mode of either a first operation mode or a second operation mode, the first operation mode is the operation mode of when the power consumption of the electrical load held by the second device is determined not to be decreased, and the second operation mode is the operation mode of when the power consumption of the electrical load held by the second device is determined to be decreased, and
when the failure has been detected in the first power supply circuit, the hardware processor determines whether the operation mode of the second device is the first operation mode or the second operation mode, and blocks the request to the first device to supply power when the operation mode is the first operation mode, and requests the first device to supply power when the operation mode is the second operation mode.

11. An information processing apparatus including a first device and a second device,
the first device comprising a first power receiving member, a cord disconnection detector, a first power supply circuit, a second switcher, and a first electrical load,
the second device comprising a second power receiving member, a second power supply circuit, a distributor, a second electrical load, and a hardware processor, wherein
the first power supply circuit converts, in a case where the first power receiving member is connected to an external power supply, power supplied via the first power receiving member from the external power supply to generate first output power,
the cord disconnection detector determines whether the first power receiving member is connected to the external power supply, and notifies the second device of non-connection when non-connection has been detected,
the second switcher switches connection between the first power supply circuit and the first electrical load to connection between the distributor and the first electrical load when the non-connection has been detected,
the first electrical load receives supply of the first output power, and receives supply of power from the second device when the non-connection has been detected,
the second power supply circuit and the second electrical load are connected to the external power supply via the second power receiving member and a power receiving path having a rated value that defines a maximum suppliable power,
the second power supply circuit converts supplied power to generate second output power,
the distributor supplies part of the second output power generated by the second power supply circuit to the first device when the non-connection has been notified,
the second electrical load receives supply of power via the second power receiving member, and
the hardware processor performs control to decrease power consumption of the second electrical load when the power supplied via the second power receiving member exceeds the rated value due to the supply of power to the first device by the distributor.

12. The information processing apparatus according to claim 1, wherein
an operation mode of the second device is restrictively changed according to suppliable power, held by the second device, to the second electrical load.

13. The information processing apparatus according to claim 1, wherein
the first power receiving member is a plurality of power cords,
the second power receiving member is a plurality of power cords,
the first electrical load and the second electrical load are respectively connected to the external power supply by the pluralities of power cords, and
the first electrical load and the second electrical load are supplied with power via at least one power cord even when the numbers of the power cords connected to the external power supply are respectively changed.

14. The information processing apparatus according to claim 13, wherein
the hardware processor further controls whether to supply power to the first electrical load and the second electrical load according to the numbers of power cords connected to the external power supply.

15. The information processing apparatus according to claim 1, wherein
the second device further includes
a display that displays whether a current operation state is normal, whether the failure is being detected in the first power supply circuit of the first device, and whether the first power receiving member is not connected to the external power supply in the first device.

16. The information processing apparatus according to claim 1, wherein
a device having a function to hold a power output for a fixed time is connected to the first power supply circuit of the first device, or the first power supply circuit of the first device has a function to hold a power output for a fixed time.

17. The information processing apparatus according to claim 1, wherein
the first device and the second device are connected with a communication line, and
the first device and the second device transmit and receive information including operation state information indicating respective operation states to and from each other via the communication line.

18. The information processing apparatus according to claim 1, wherein
the external power supply supplies alternating-current power,
each of the first power supply circuit and the second power supply circuit converts an alternating current to generate a direct current,
the distributor supplies a direct current to the first device, and
an alternating current is supplied from the external power supply to the second device via the second power receiving member.

19. The information processing apparatus according to claim 11, wherein
the external power supply supplies alternating-current power,
each of the first power supply circuit and the second power supply circuit converts an alternating current to generate a direct current, and
the distributor supplies a direct current to the first device.

20. The information processing apparatus according to claim 1, wherein
the first device is a print server, a mail server, a web server, a DHCP server, a DNS server, or a server having a function of virus check, system update, data backup, or simulation.

21. The information processing apparatus according to claim 1, wherein
the second device is an image forming device that forms an image on a recording sheet.

22. The information processing apparatus according to claim 21, wherein
the second device includes a fixer that fixes a toner image on the recording sheet by a heating member and a pressure member, and the second electrical load is the heating member, and
when the failure has been detected in the first power supply circuit, the hardware processor determines whether to receive supply of power from the external power supply via the second power receiving member according to whether an operation mode is an operation mode to fix the toner image on the recording sheet, using the fixer.

23. The information processing apparatus according to claim 21, wherein
the hardware processor calculates power consumption required in the second device according to the number of prints or a printing rate in each recording sheet in the second device as the image forming device, and performs an image forming process and conveyance of the recording sheet at lower speeds than a normal speed of an image forming process and a normal conveyance speed of the recording sheet.

24. The information processing apparatus according to claim 1, wherein
the first device is a server having a server function,
the second device is an image forming device, and
in the information processing apparatus, the server and the image forming device are integrally configured.

25. The information processing apparatus according to claim 1, wherein
the first device detachably holds the electrical load.

26. A control method used in an information processing apparatus including a first device and a second device,
the first device including a first power receiving member, a first switcher, a first power supply circuit, a failure detector, a second switcher, and a first electrical load, the second device including a second power receiving member, a second power supply circuit, a distributor, a third switcher, a second electrical load, and a hardware processor,
the control method including a first control method used in the first device and a second control method used in the second device,
the first control method comprising:
switching connection between the first power receiving member connected to an external power supply and the first power supply circuit to connection between the first power receiving member and the third switcher by a request of the second device, by the first switcher;
converting power supplied via the first power receiving member to generate first output power, by the first power supply circuit, in a case where the first power supply circuit is connected to the first power receiving member by the first switcher;
detecting a failure in the first power supply circuit, and notifying the second device of detection of the failure when having detected the failure, by the failure detector; and
switching connection between the first power supply circuit and the first electrical load to connection between the distributor and the first electrical load when the failure has been detected, by the second switcher, wherein
the first electrical load receives supply of the first output power from the first power supply circuit, and receives supply of power from the distributor when the failure has been detected, and
the second power supply circuit and the third switcher are connected to the external power supply via the second power receiving member and a power receiving path having a rated value that defines a maximum suppliable power,
the second control method comprising:
converting supplied power to generate second output power, by the second power supply circuit;
supplying part of the second output power to the second switcher when the failure has been notified, by the distributor; and
switching connection between the second power receiving member and the second electrical load to connection between the second power receiving member and a part of the second electrical load and connection between the first switcher and a remaining part of the second electrical load when the failure has been notified, by the third switcher, wherein
the second electrical load receives supply of power via the second power receiving member, and the part of the second electrical load receives supply of power via the second power receiving member and the remaining part of the second electrical load receives supply of power via the first power receiving member when the failure has been detected,
the second control method further comprising:
requesting the first device to supply power when the power supplied via the second power receiving member exceeds the rated value due to the supply of power to the second switcher by the distributor, by the hardware processor.

27. A non-transitory recording medium storing a computer readable program for control used in an information processing apparatus including a first device and a second device,
the first device including a first power receiving member, a first switcher, a first power supply circuit, a failure detector, a second switcher, and a first electrical load, the second device including a second power receiving member, a second power supply circuit, a distributor, a third switcher, a second electrical load, and a hardware processor,
the program causing the information processing apparatus as a computer to perform:
performing control to switch connection between the first power receiving member connected to an external power supply and the first power supply circuit to connection between the first power receiving member and the third switcher by a request of the second device;
performing control to convert power supplied via the first power receiving member to generate first output power in a case where the first power supply circuit is connected to the first power receiving member by the first switcher;
performing control to detect a failure in the first power supply circuit, and notifying the second device of detection of the failure when having detected the failure; and
performing control to switch connection between the first power supply circuit and the first electrical load to connection between the distributor and the first electrical load when the failure has been detected, wherein
the first electrical load receives supply of the first output power from the first power supply circuit, and receives supply of power from the distributor when the failure has been detected, and
the second power supply circuit and the third switcher are connected to the external power supply via the second power receiving member and a power receiving path having a rated value that defines a maximum suppliable power,
the program causing the information processing apparatus as a computer to further perform:
performing control to generate second output power by converting supplied power;
performing control to supply part of the second output power to the second switcher when the failure has been notified; and
performing control to switch connection between the second power receiving member and the second electrical load to connection between the second power receiving member and a part of the second electrical load and connection between the first switcher and a remaining part of the second electrical load when the failure has been notified, wherein
the second electrical load receives supply of power via the second power receiving member, and the part of the second electrical load receives supply of power via the second power receiving member and the remaining part of the second electrical load receives supply of power via the first power receiving member when the failure has been detected, and
the program causing the information processing apparatus as a computer to further perform:
requesting the first device to supply power when the power supplied via the second power receiving member exceeds the rated value due to the supply of power to the second switcher by the distributor.

28. A control method used in an information processing apparatus including a first device and a second device,
the first device including a first power receiving member, a cord disconnection detector, a first power supply circuit, a second switcher, and a first electrical load, the second device including a second power receiving member, a second power supply circuit, a distributor, a second electrical load, and a hardware processor, and
the control method including a first control method used in the first device and a second control method used in the second device,
the first control method comprising:
converting, in a case where the first power receiving member is connected to an external power supply, power supplied via the first power receiving member from the external power supply to generate first output power, by the first power supply circuit;
determining whether the first power receiving member is connected to the external power supply, and notifies the second device of non-connection when non-connection has been detected, by the cord disconnection detector; and
switching connection between the first power supply circuit and the first electrical load to connection between the distributor and the first electrical load when the non-connection has been detected, by the second switcher, wherein
the first electrical load receives supply of the first output power, and receives supply of power from the second device when the non-connection has been detected, and
the second power supply circuit and the second electrical load are connected to the external power supply via the second power receiving member and a power receiving path having a rated value that defines a maximum suppliable power,
the second control method comprising:
converting supplied power to generate second output power, by the second power supply circuit; and
supplying part of the second output power generated by the second power supply circuit to the first device when the non-connection has been notified, by the distributor, wherein
the second electrical load receives supply of power via the second power receiving member,
the second control method further comprising:
performing control to decrease power consumption of the second electrical load when the power supplied via the second power receiving member exceeds the rated value due to the supply of power to the first device by the distributor, by the hardware processor.

29. A non-transitory recording medium storing a computer readable program for control used in an information processing apparatus including a first device and a second device,
the first device including a first power receiving member, a cord disconnection detector, a first power supply circuit, a second switcher, and a first electrical load, the second device including a second power receiving member, a second power supply circuit, a distributor, a second electrical load, and a hardware processor,
the program causing the information processing apparatus as a computer to perform:
performing control to convert, in a case where the first power receiving member is connected to an external power supply, power supplied via the first power receiving member from the external power supply to generate first output power;
performing control to determine whether the first power receiving member is connected to the external power supply, and notifies the second device of non-connection when non-connection has been detected; and
performing control to switch connection between the first power supply circuit and the first electrical load to connection between the distributor and the first electrical load when the non-connection has been detected, wherein
the first electrical load receives supply of the first output power, and receives supply of power from the second device when the non-connection has been detected, and
the second power supply circuit and the second electrical load are connected to the external power supply via the second power receiving member and a power receiving path having a rated value that defines a maximum suppliable power,
the program causing the information processing apparatus as a computer to further perform:
performing control to convert supplied power to generate second output power; and
performing control to supply part of the second output power generated by the second power supply circuit to the first device when the non-connection has been notified, wherein
the second electrical load receives supply of power via the second power receiving member, and
the program further causing the information processing apparatus as a computer to further perform:
performing control to decrease power consumption of the second electrical load when the power supplied via the second power receiving member exceeds the rated value due to the supply of power to the first device by the distributor.

30. The information processing apparatus according to claim 11, wherein
an operation mode of the second device is restrictively changed according to suppliable power, held by the second device, to the second electrical load.

31. The information processing apparatus according to claim 11, wherein
the first power receiving member is a plurality of power cords,
the second power receiving member is a plurality of power cords,
the first electrical load and the second electrical load are respectively connected to the external power supply by the pluralities of power cords, and
the first electrical load and the second electrical load are supplied with power via at least one power cord even when the numbers of the power cords connected to the external power supply are respectively changed.

32. The information processing apparatus according to claim 11, wherein
the second device further includes
a display that displays whether a current operation state is normal, whether the failure is being detected in the first power supply circuit of the first device, and whether the first power receiving member is not connected to the external power supply in the first device.

33. The information processing apparatus according to claim 11, wherein
a device having a function to hold a power output for a fixed time is connected to the first power supply circuit of the first device, or the first power supply circuit of the first device has a function to hold a power output for a fixed time.

34. The information processing apparatus according to claim 11, wherein
the first device and the second device are connected with a communication line, and
the first device and the second device transmit and receive information including operation state information indicating respective operation states to and from each other via the communication line.

35. The information processing apparatus according to claim 11, wherein
the first device is a print server, a mail server, a web server, a DHCP server, a DNS server, or a server having a function of virus check, system update, data backup, or simulation.

36. The information processing apparatus according to claim 11, wherein
the second device is an image forming device that forms an image on a recording sheet.

37. The information processing apparatus according to claim 11, wherein
the first device is a server having a server function,
the second device is an image forming device, and
in the information processing apparatus, the server and the image forming device are integrally configured.

38. The information processing apparatus according to claim 11, wherein
the first device detachably holds the electrical load.
